(19) United States
(12) Patent Application Publication
(10) Pub. No.: US 2009/0214884 A1
(43) Pub. Date: Aug. 27, 2009

(54) Gravitation deflecting mechanisms

(76) Inventor: Roger Ellman, Santa Rosa, CA (US)

Correspondence Address: Roger Ellman, 320 Gemma Circle, Santa Rosa, CA, 95404, US

(21) Appl. No.: 12/072,302

(22) Filed: Feb. 27, 2008

(51) Int. Cl. C30B 29/00

(52) U.S. Cl. 428/543

(57) ABSTRACT

This disclosure presents and claims means for the modification of local gravitation by reducing its strength, speed of propagation, and/or its direction of action and presents and claims various uses of those means. The new technology involved is the recognition that light and gravitation flow in the same medium; that the observed effects of gravitational lensing and light diffraction demonstrate the gravitational field of atoms deflecting the flow of that common light/gravitation medium; that a suitable arrangement of atoms thus could produce a desired deflection of gravitation; and that the atomic structure of a cubic crystal [for example Silicon] is suitable for that application.

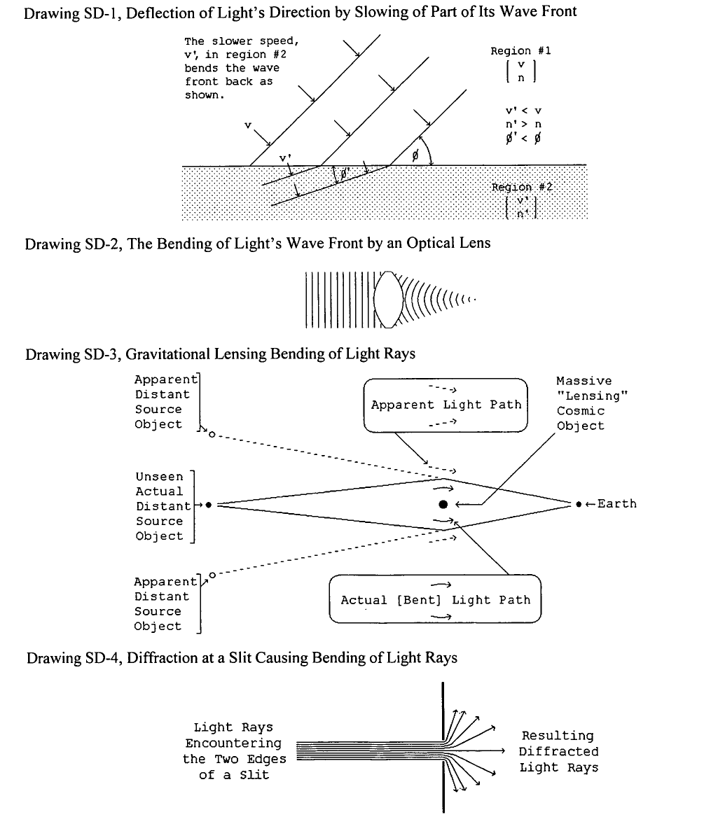

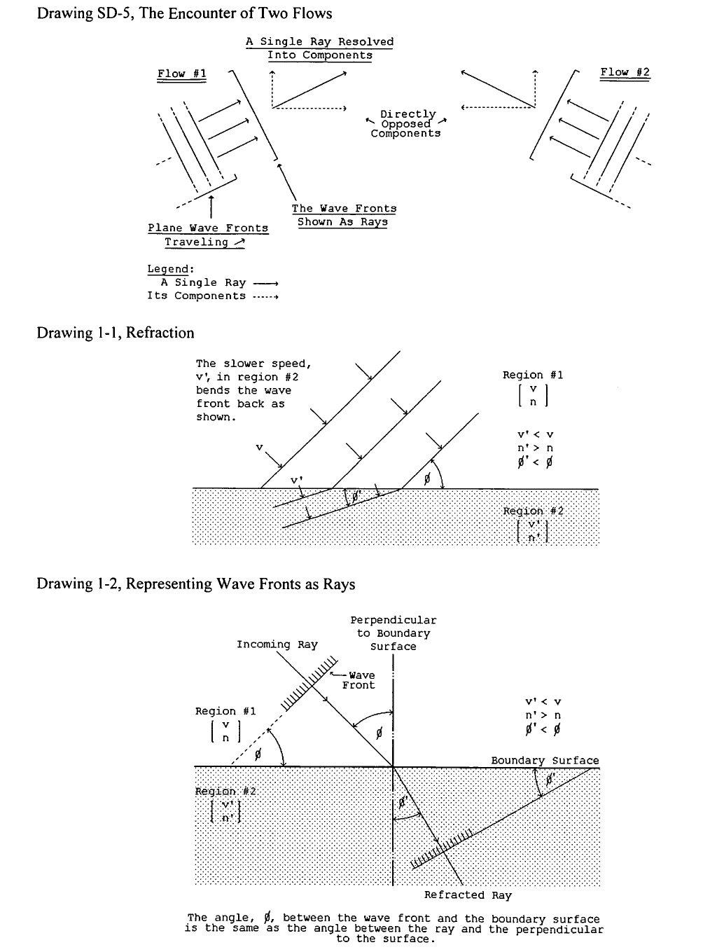

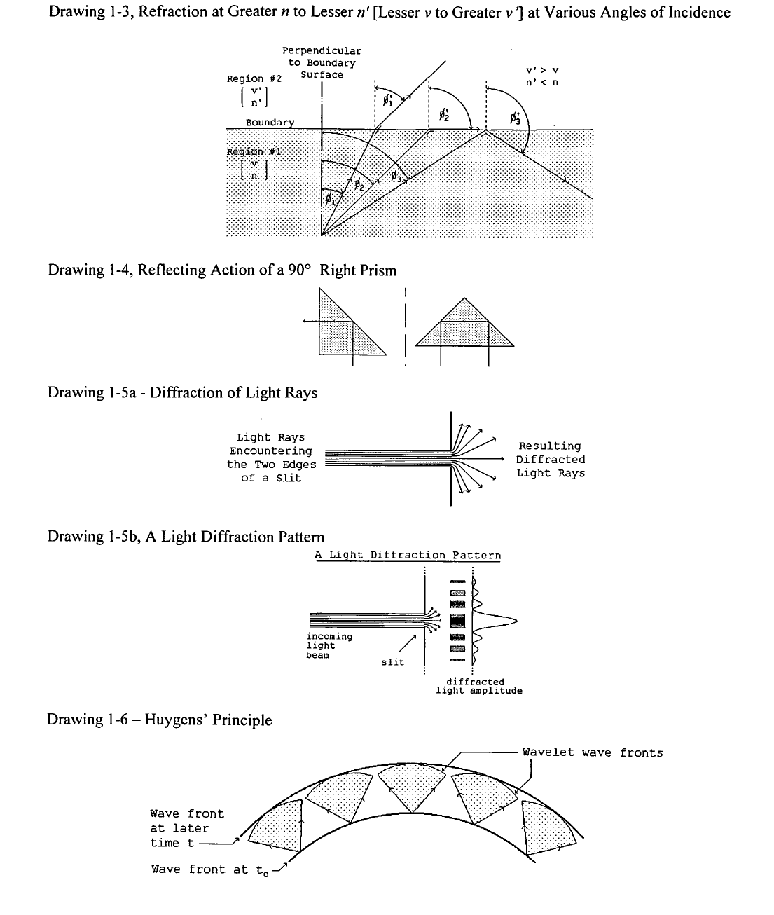

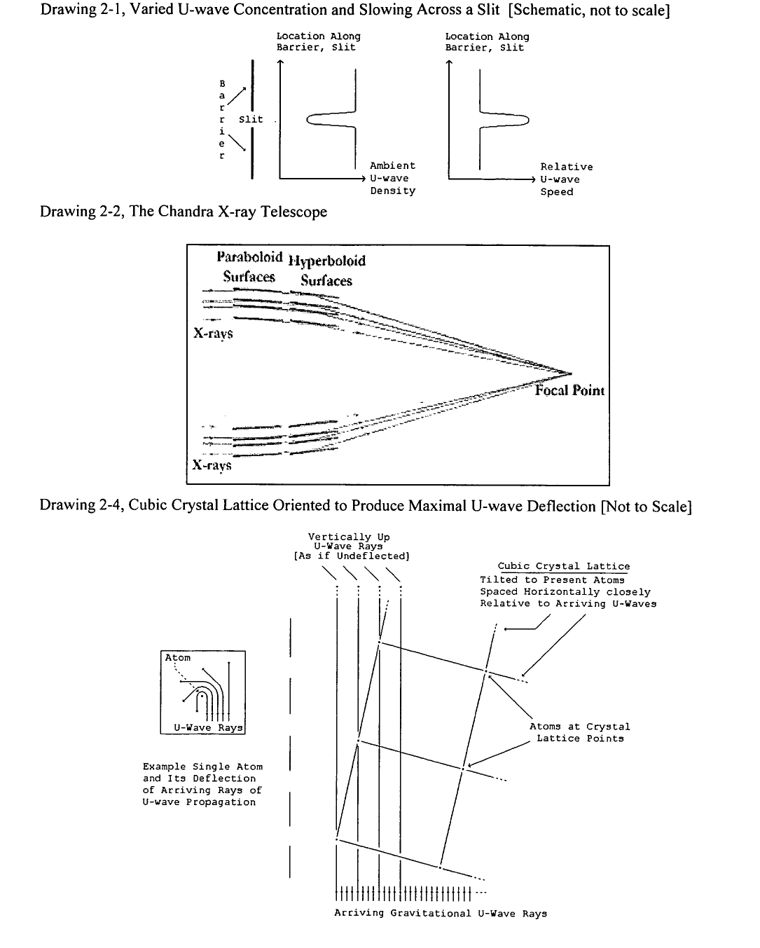

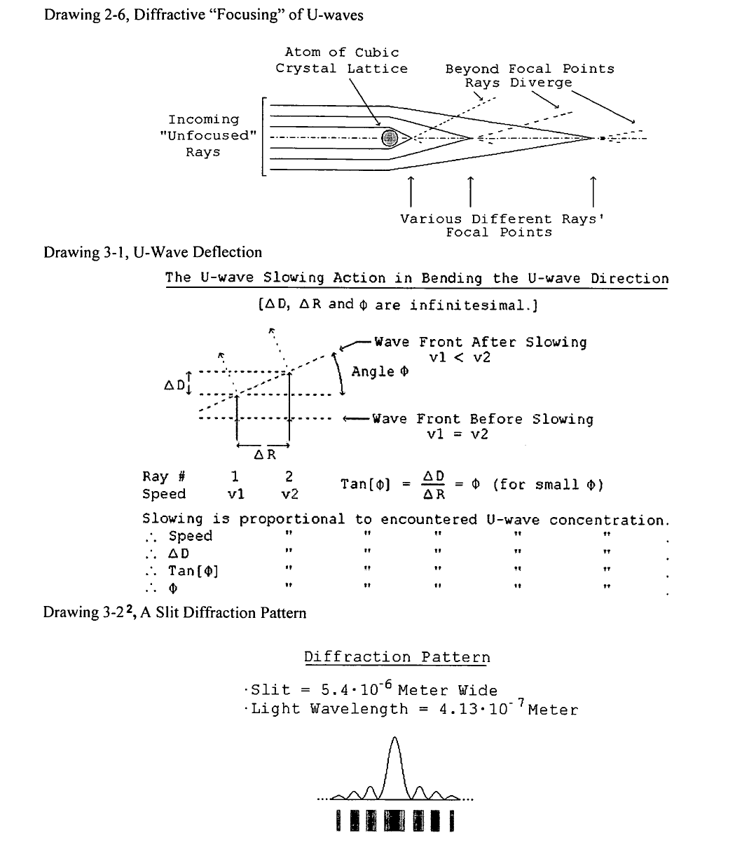

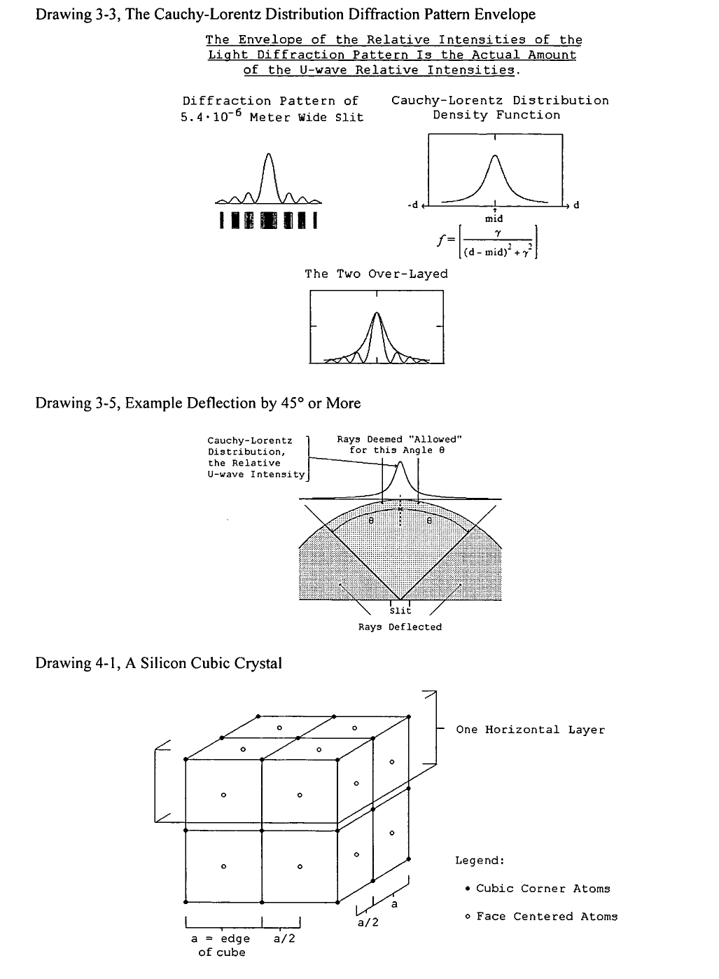

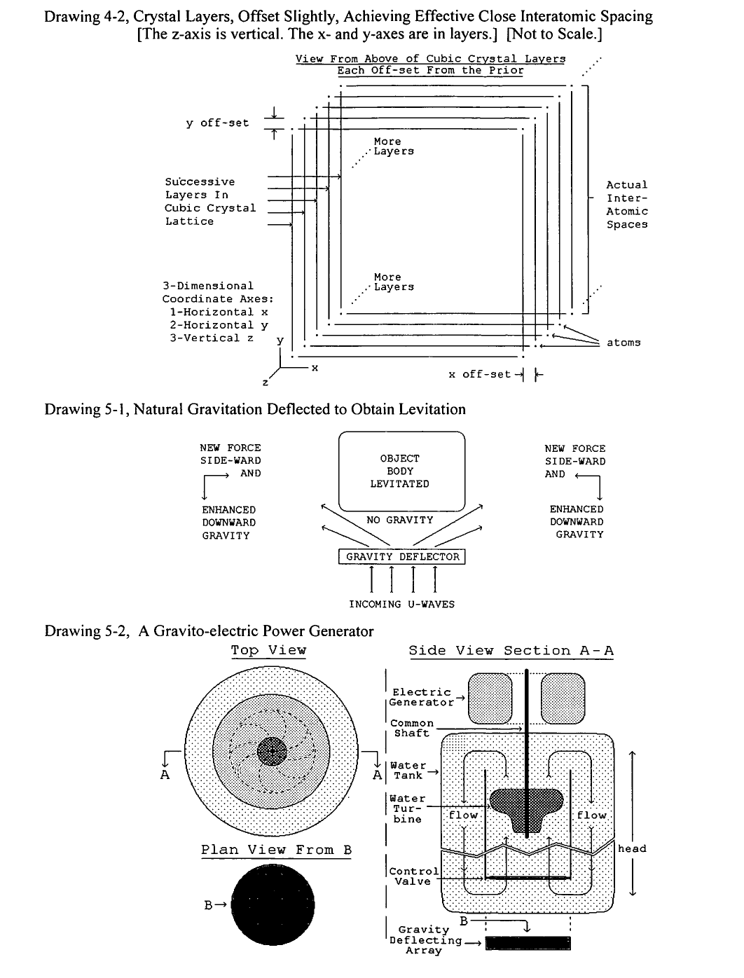

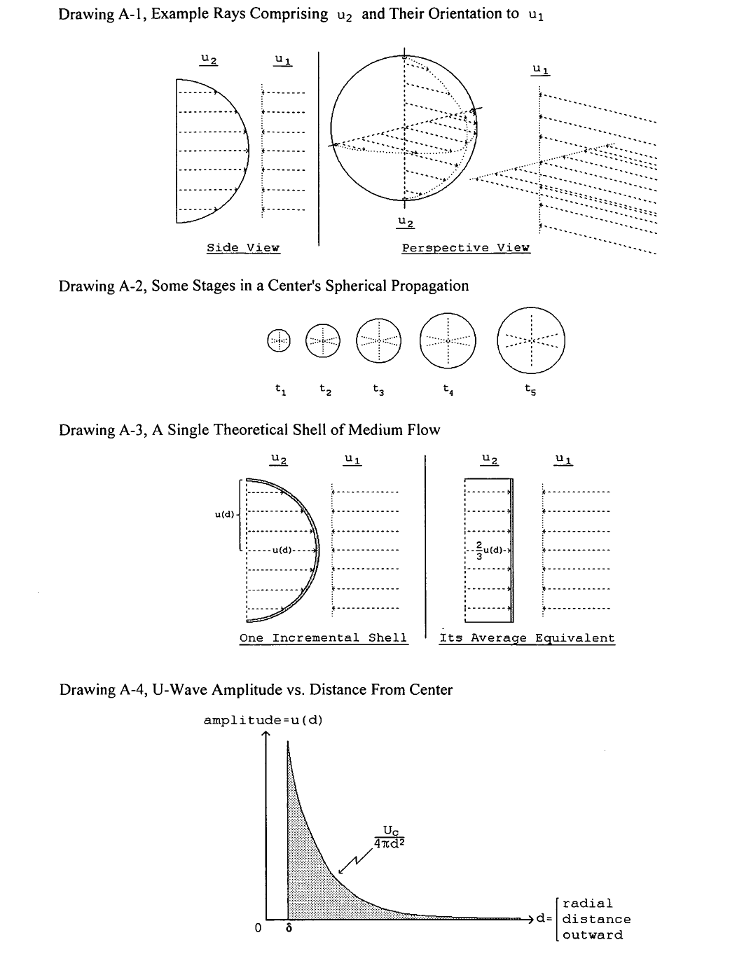

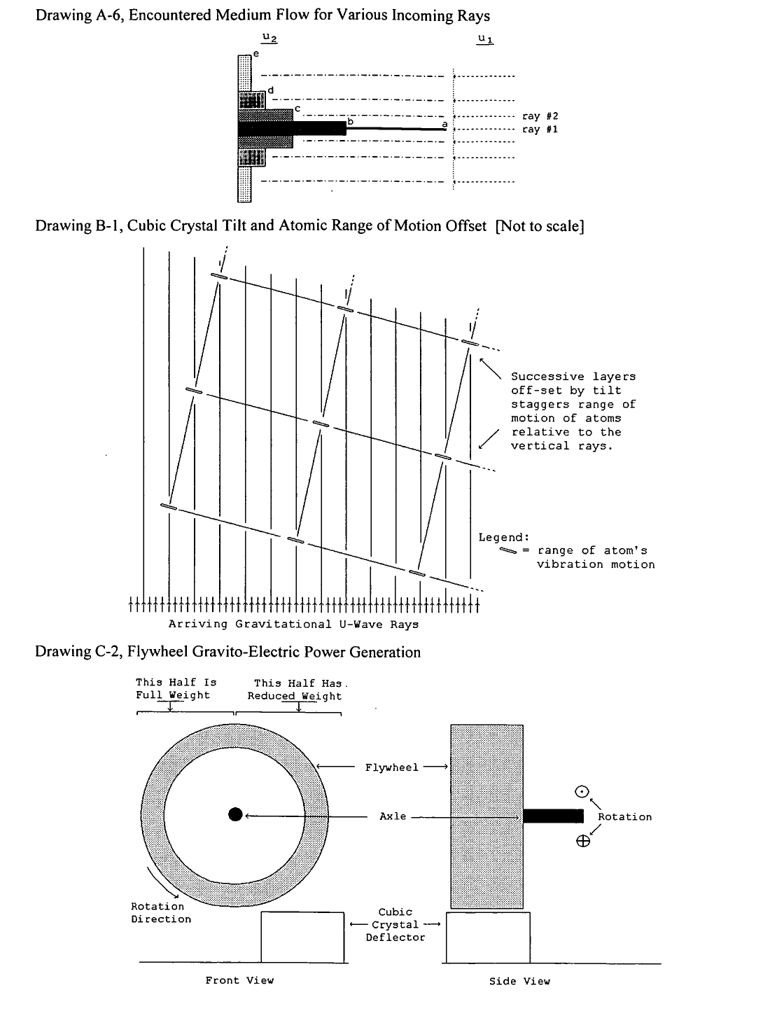

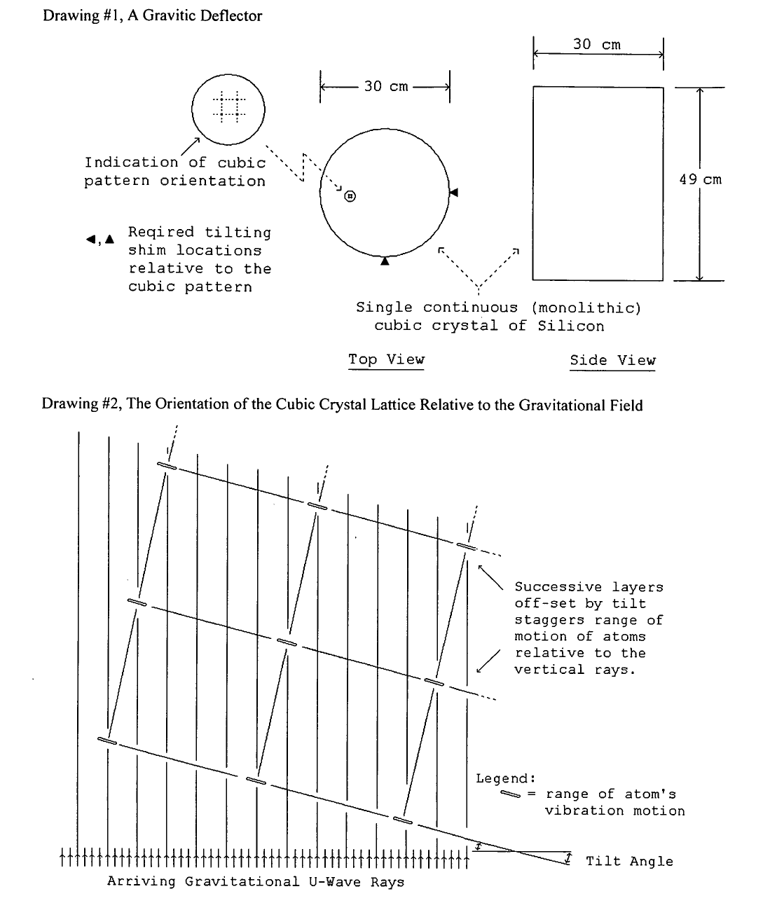

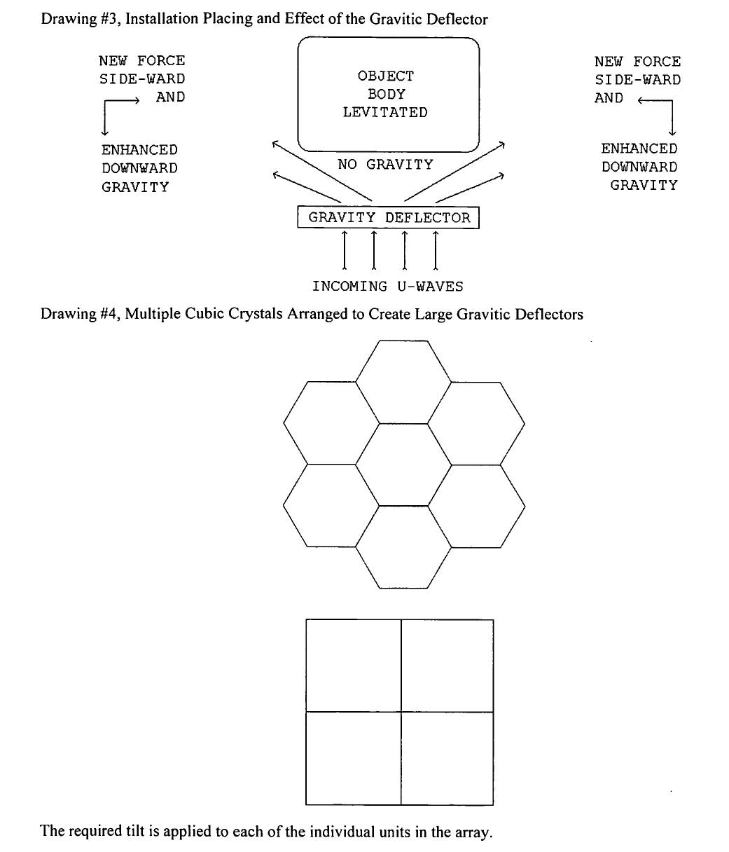

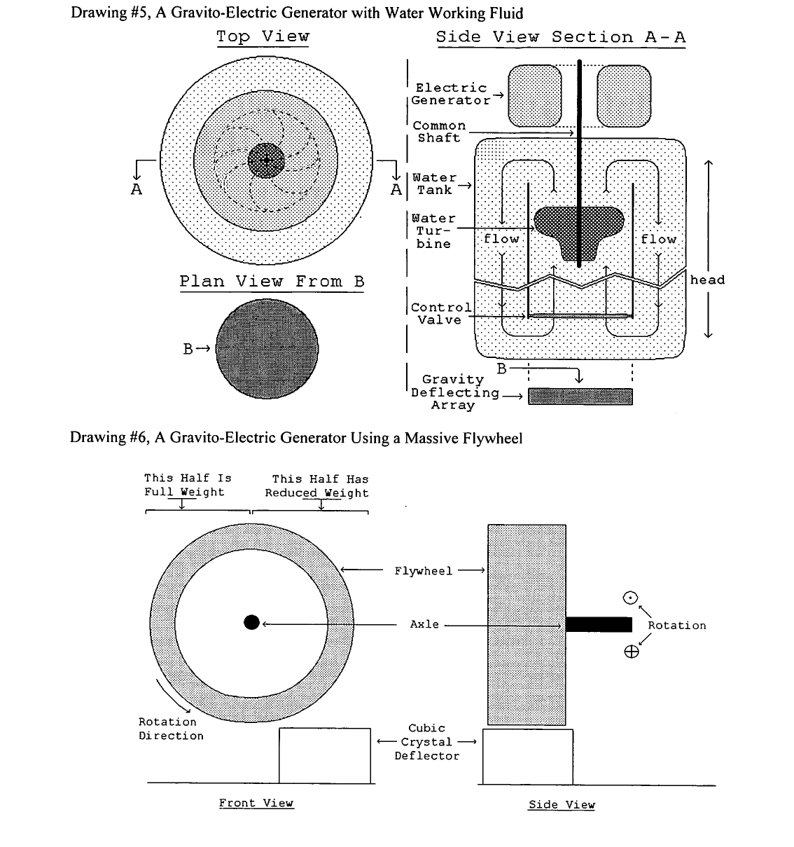

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### BACKGROUND OF THE INVENTION

### Preface

### Introduction

It is now possible to deflect gravitational action away from an object so that the object is partially levitated. That effect makes gravito-electric power generation technologically feasible. Such plants would be similar to hydroelectric plants and would have their advantages of non-need of fuel and non-pollution of the environment. However, gravito-electric plants would be much smaller; their location would not be restricted to suitable water elevations, and the plants and their produced energy would be much less expensive.

With suitable design such plants could power all-electric: ships, aircraft, and land vehicles. Gravito-electric power can be made available now and would essentially solve the problem of global warming.

### Summary Development

Light normally travels in a straight direction. But, when some effect slows a portion of the light wave front the direction of the light is deflected. In Drawing SD-1, the shaded area propagates the arriving light at a slower velocity, v′, than the original velocity, v, [its index of refraction, n′, is greater] so that the direction of the wave front is deflected from its original direction.

A slowing of part of its wave front is the mechanism of all bending or deflecting of light. In an optical lens, Drawing SD-2, light propagates more slowly in the lens material than when outside the lens. The amount of slowing in different parts of the lens is set by the thickness of the lens at each part. In Drawing SD-2 the light passing through the center of the lens is slowed more than that passing near the edges of the lens. The result is the curving of the light wave front.

“Gravitational lensing”, Drawing SD-3, is an astronomically observed effect in which light from a cosmic object too far distant to be directly observed from Earth becomes observable because a large cosmic mass [the “lens”], located between Earth observers and that distant object, deflects the light from the distant object as if focusing it, somewhat concentrating its light toward Earth enough for it to be observed from Earth. The light rays are so bent because the lensing object slows more the portion of the wave front that is nearer to it than it slows the farther away portion of the wave front.

The same effect occurs on a much smaller scale in the diffraction of light at the two edges of a slit cut in a flat thin piece of opaque material, Drawing SD-4. The bending is greater near the edges of the slit because the slowing is greater there. The effect of the denser material in which the slit is cut slows the portion of the wave front that is nearer to it more than the portion of the wave front in the middle of the slit.

In both of these cases, gravitational lensing and slit diffraction, the direction of the wave front is changed because part of the wave front is slowed relative to the rest of it. In the case of gravitational lensing the part of the wave front nearer to the “massive lensing cosmic object” is slowed more. In the case of diffraction at a slit the part of the wave front nearer to the solid, opaque material in which the slit is cut is slowed more.

But, neither of the cases, gravitational lensing and slit diffraction, involves the wave front passing from traveling through one substance to another as in the original illustration, above. The wave front in the gravitational lensing case is traveling only through cosmic space. The wave front in the slit diffraction case is traveling only through air. There is no substance change to produce the slowing. What is it that slows part of the wave front thus producing the deflection?

In the case of gravitational lensing the answer is that the effect is caused by gravitation. There is no other physical effect available. But how does gravitation produce slowing of part of the incoming wave front so as to deflect it? Gravitation, at least as it is generally known and experienced, causes acceleration, not slowing.

Field: Electro-Magnetic (Light) and Gravitational (Gravity)

Light

Given two particles [e.g. electrons or protons] that have electric charges, the particles being separated and with the usual electric [Coulomb] force between them, if one of the charged particles is moved the change can produce no effect on the other charge until a time equal to the distance between them divided by the speed of light, c, has elapsed.

For that time delay to happen there must be something flowing from one charge to the other at speed c [a fundamental constant of the universe] and each charge must be the source of such a flow.

That electric effect is radially outward from each charge, therefore every charge must be propagating such a flow radially outward in all directions from itself, which flow must be the “electric field”.

When such a charge moves with varying speed it propagates a pattern called electromagnetic field outward into space. Light is that pattern, that field traveling in space. Since light's source is a charged particle that, whether the particle is moving or not, is continuously emitting its radially outward flow that carries the affect of its charge, then light's electromagnetic field is a pattern of variations in that flow due to the charge's varying speed.

Gravity

Given two masses, i.e. particles [e.g. electrons or protons] that have mass, being separated and with the usual gravitational force [attraction] between them, if one of the masses is moved the change can produce no effect on the other mass until a time equal to the distance between them divided by the speed of light, c, has elapsed.

For that time delay to happen there must be something flowing from one mass to the other at speed c and each particle, each mass must be the source of such a flow.

That gravitational effect is radially outward from each mass, therefore every mass must be propagating such a flow radially outward in all directions from itself, which flow must be the “gravitational field”.

That Flow

We therefore find that the fundamental particles of atoms, which have electric charge and gravitational mass must have something flowing outward continuously from them and:

Either the particles each have two separate outward flows, one for electric and electromagnetic field and another for gravitation, or

They each have one common universal outward flow that acts to produce all of the effects: electric field, electromagnetic field [light] and gravitational field [gravity].

There is clearly no contest between the alternatives. It would be absurd for there to be two separate, but simultaneous, independent outward flows, for the two different purposes. And, the single universal outward flow from atoms means that gravitational field can have an affect on light, on electromagnetic field because they both are the same medium—the universal outward flow.

Gravitational Slowing/Deflection of Light

Because that universal outward flow originates at each particle and flows radially outward in all directions its density or concentration decreases inversely as the square of distance from the source of the flow. At a large distance from the source the wave front of a very small portion of the total spherical outward flow is essentially flat—a “plane flow”.

Two such universal flows directly encountering each other “head on” [flowing exactly toward each other] interfere with the other, that is each slows the flow of the other. The effect is proportional to the density or concentration of each flow.

When two such flows encounter each other but not directly “head on” then each flow can be analyzed into two components: one directly opposed to the other's flow and one at right angles to that direction per Drawing SD-5.

Picturing Flow #1 of that Drawing as that from a “lensing” gravitational mass and Flow #2 as that of the light from a distant object, then the Drawing depicts how the flow of the “lens” slows part of the wave front of the flow of the propagating light. The slowing is greater for rays of light that pass close to the lens and is less for those farther out. Thus the wave front of the light is deflected or bent.

That same effect, on a vastly reduced scale, produces the deflection, the bending of the light direction that is seen in slit diffraction. In the diffraction effect the role of the “massive lensing cosmic object” is performed by the individual atoms making up the opaque thin material in which the slit is cut.

Thus gravitation produces deflection of the flow that carries light. That flow is identical to the flow that carries gravitation. Thus the gravitational flow from one mass can produce deflection of the gravitational flow from another mass.

Gravitation Deflector Design

The task, then, is to more thoroughly analyze develop and quantify this effect so that practical implementation can be designed.

That is the role of the remainder of this analysis as developed in the following sections.

A result is that the desired effect, deflection of gravitation, can be produced by using the structure of a cubic crystal such as those from which slices or wafers are cut for the making of electronic “chips”.

Section 1—Fundamentals and the Optics Analogy

Gravitics treats the behavior and management of gravitation, the name being analogous to optics which treats the behavior and management of light.

### Introduction

Universal physics, as developed in The Origin and Its Meaning¹ by Roger Ellman© 1997, shows that all material reality consists of centers-of-oscillation and the flow outward from them of medium. The core of each center-of-oscillation consists of an original [at the universe' beginning] supply of medium, which has been and continues to be very gradually depleted by the loss of medium to the outward flow, that process is the universal decay (exponentially with a time constant on the order of over 11 billion years). [1] R. Ellman, The Origin and Its Meaning, The-Origin Foundation, Inc., http://www.The-Origin.org, 1997. [The book may be downloaded in .pdf files from http://ww v.The-Origin.org/download.htm].

The medium in the core and the resulting medium flowing outward both oscillate. That which is oscillating is the medium amount. The core oscillation and the propagated oscillatory wave are of the form

$$\begin{matrix}Core = \pm {U}_{c} \cdot {ɛ}^{- t / τ} \cdot [ 1 - Cos [ 2 π ( f \cdot t ) ] ] & ( 1 \text{-} 1 ) \\ Wave = \pm {U}_{c} \cdot {ɛ}^{- t / τ} \cdot [ 1 - Cos [ 2 π ( f \cdot t ) - \frac{d}{λ} ] ] \cdot \frac{1}{4 π \cdot {d}^{2}} & ( 1 \text{-} 2 )\end{matrix}$$

where the “±” is because there are cores (and their propagated waves) oscillating in medium (−) that is opposite to the other medium (+). The total amount of medium in each of the two types is the same so that collectively they sum to zero, to the original nothing before the beginning of the universe.

Equation (1-2), the wave, describes an oscillation in time, t, after the Beginning, the Big Bang, (at t=0) at any particular distance, d, from the source core (at d=0). It also describes an inverse-square decaying oscillatory distribution of medium in space, d, for any particular time, t.

The amplitude, U_{c}, in the above equations is the original amplitude at t=0, d=0. The frequency, f, determines the type particle that the core is: proton, electron, etc. The frequency is very large, on the order of 10²³ Hz (cycles per second) for a proton. The factor, ¼π·d², in the Wave formulation is because the waves, referred to as U-waves (Universal waves), propagate radially outward in all directions from the core. That causes their amplitude to decrease inversely as the square of distance from the core.

δ [Greek lambda] is the wavelength of the U-wave propagation in space and equals c/f, where c is the speed of propagation of the medium. That speed is what we refer to as the speed of light in free space.

The terminology “refer to” is used because light does not travel in itself. That which we call light is merely a modulation, an imprint, on the propagating U-waves. Because the U-waves propagate, the light imprint on them travels with the U-waves on which it is imprinted, so traveling at the speed of those U-waves. [But see further below on the speed of light travel in various materials.]

This nature of light, the distinction between U-waves, themselves, and a light modulatory imprint that may or may not be present on a particular sample of U-waves is important. We tend to think of light as an independent thing in itself because of not having known of U-waves and its dependency on them. The distinction modifies some of the traditional physics understandings of the cause of some optical behaviors.

Gravitics is the physics of U-wave flow and has as its objective the planned, useful control of gravitation by control of its cause, an aspect of U-wave flow. The control of U-wave flow could be used for controlling any of the effects produced by U-waves, which include: electrostatic effects, magnetic effects and gravitation. All of those except gravitation are already well managed by the techniques of electricity, magnetism and electronics. But, gravitation has remained beyond our control. It is therefore primarily sought to use the principles of gravitics to control the gravitation effect caused by U-waves, hence the name gravitics in analogy to optics, which is the physics of the flow of light.

The analogy to optics, because light is merely a fixed imprint or modulation on flowing U-waves, leads to examining the thoroughly developed science of optics in search of information on U-wave behavior.

### Optics

The behavior of light is complex and involves some aspects of its behavior that U-wave flow does not. The reason for that is that light is a transverse oscillation of an electromagnetic propagation. U-wave propagation is a longitudinal oscillation of flowing medium amount.

Light interacts with matter in various ways. It can be absorbed at certain discrete frequencies by atomic orbital electrons, elevating them to a higher discrete orbit by the energy acquired from the light. That energy can later be partially or completely re-emitted as light at certain discrete frequencies by an electron falling to a lower discrete orbit.

Light can otherwise be absorbed and immediately re-radiated at a variety of frequencies by atomic electrons. In this case the frequency restrictions involved with atomic orbital electrons are not necessarily involved. This is the mechanism of reflection, a process in which the light incident on the reflecting surface is absorbed and re-radiated in the reflective direction, that direction mandated by conservation of the linear momentum in the incident light.

In passing through transparent or translucent material the electromagnetic field of light interacts with the electric charges in the matter, primarily with its electrons. That interaction tends to slow the speed of the light while traversing the matter. This electromagnetic effect varies with the frequency of the light so that the amount of slowing of the light so varies.

The terminology “light” means all transverse oscillation of an electromagnetic propagation imprinted on flowing U-waves. That includes “light” at lower frequencies than visible light [e.g. infra-red or “heat” and radio waves] and at higher frequencies [e.g. ultra-violet, x-rays]. The energy that the light carries is directly proportional to its frequency.

But, the U-waves which underlie the flow of light are not transverse electromagnetic field but longitudinal medium flow oscillating in its usual [1—Cosine] manner. That flow does not exhibit the behavior of light that is dependent on its electromagnetic nature, but it does exhibit the behavior of light that is dependent on its wave nature—or rather, just the inverse—light exhibits the behavior of medium flow that is due to the wave nature of medium flow plus some additional behavior due to the E-M nature of light.

The optical behavior of light includes the phenomena: speed, refraction, diffraction, reflection, interference and polarization.

Speed is, of course, simply the rate of flow.

Refraction. While the speed of light in free space is a constant (neglecting the very gradual universal decay), in different environments (e.g. air, glass, water) it is different. Refraction is the bending of the direction of flow when it passes from a region of one speed to one of another speed.

Diffraction. When the flow of light passes an edge of an opaque substance the flow on the far side of that boundary is seen to diffuse into the “shadow” area. One of the more significant instances of this is the passage of light through a slit, which is two opaque edges very near to each other

Reflection. Light “bounces” off of many surfaces.

Interference. If light waves suitably encounter other light waves a standing wave pattern with its characteristic maxima and minima results.

Polarization. Light the oscillation of which is in a particular direction.

Speed

In optics, rather than using the speed of propagation directly in analysis a related quantity, the index

$$Index of Refraction \\ n = \frac{c}{v} \qquad ( 1 \text{-} 3 )$$

where n=index for some particular substance
c=sped of light in free space
v=speed of light in the substance

Some typical values are:

| Substance | n |
|---|---|
| free space | 1 (exactly) |
| atmosphere | 1.00029 |
| water | 1.33 |
| glass | 1.46-1.96 |

Because light travels as an imprint on U-waves carrying it, the “speed of light” in optics is actually the speed of propagation of the underlying U-waves as further reduced by light's interaction with any matter through which it passes. For U-waves always and for light in free space, which has no matter with which the light can interact, that quantity, c, is per equation (1-4), below

$$c = \frac{1}{\sqrt{{μ}_{0} \cdot {ɛ}_{0}}} \qquad ( 1 \text{-} 4 )$$

μ₀ is the permeability or magnetic constant of free space, i.e. of the “vacuum”.

ε₀ is its [di]electric constant.

and in any substance it is for light, v,

$$v = \frac{1}{\sqrt{μ \cdot ɛ}} \qquad ( 1 \text{-} 5 )$$

where μ and ε are the constants for the substance through which the light is passing.

In addition to the slowing of light by it's electromagnetic interaction with electrons in matter through which it passes, the matter slows the speed of the actual U-waves carrying the light. That slowing is the same effect, discussed in The Origin and Its Meaning, as that which produces the mass effect by focusing of U-waves and produces the gravitational effect. The slowing depends directly on the U-wave concentrations involved. [See equation (2-1) in the following Section 2 and its related discussion for details on this effect.]

Refraction

Refraction occurs when a wave, propagating through a region of one propagation speed, v (one index of refraction, n=c/v), passes into another region of propagation speed, v′ (index of refraction, n′=c/v′). In the new region the wave front is bent at an angle relative to that in the old region. This is illustrated in Drawing 1-1.

U-waves, and unfocused light travel radially outward from their source. The wave front of their outward propagation is the surface of a sphere. For clarity in Drawing 1-1 the wave front is taken to be plane, as would the wave front from a far distant source appear to approximate.

From the geometry of Drawing 1-1 it can readily be shown that

$$\frac{Sin ∅}{Sin {∅}^{′}} = \frac{v}{{v}^{′}} \qquad ( 1 \text{-} 6 )$$

from which, using equation (1-3), the following, Snell's Law, is obtained.

n·Sin φ=n′·Sin φ′ (1-7)

In analyzing these aspects of wave behavior it is more convenient to deal in terms of rays rather than wave fronts. The ray representing a wave front is a straight line pointing in the direction of propagation of the waves, that is, perpendicular to the wave front [because U-wave and light propagation are in a straight line until some speed change causes bending of that path]. Drawing 1-2 depicts the refraction of a wave in terms of rays.

In the Drawing 1-2 depiction the wave passes from a region of greater speed of propagation, v, to one of lesser speed (smaller index of refraction, n, to greater). Under those conditions the ray is refracted toward the perpendicular to the boundary surface as shown in the Drawing.

In the opposite situation, the wave passing from a region of less speed of propagation, v, to one of greater speed (greater index of refraction, n, to smaller), the ray is refracted away from the perpendicular to the boundary surface. Drawing 1-3 shows several different amounts of such refraction as the incoming wave encounters the boundary at different angles, φ.

The angle φ₂ in Drawing 1-3 is referred to as the critical angle because it represents the boundary case between the incident ray being bent to a new direction in the new region and its being bent so much that it re-enters its initial region. For that boundary case, the middle ray in Drawing 1-3, incident at angle φ₂, must be refracted at angle φ₂′90°, as in the Drawing.

That is, from Snell's Law, equation (1-7),

$$\begin{matrix}n \cdot Sin {∅}_{2} = {n}^{′} \cdot Sin {∅}_{2}^{′} \\ = {n}^{′} \cdot Sin [ 90 ° ] \\ = {n}^{′} \\ Sin {∅}_{2} = \frac{{n}^{′}}{n} \\ = Sin {∅}_{critical}\end{matrix} \qquad ( 1 \text{-} 8 )$$

the critical angle occurs when the sine of the angle of incidence equals n′/n, which is less than 1.0 when passing from greater n to lesser n′ (lesser speed to greater speed).

When the angle of incidence is greater than the critical angle, as in the case of φ₃, then the ray re-enters region #1 from region #2. It is then again refracted in the usual manner. That means that the ray is bent toward the perpendicular to the boundary surface at the new angle of incidence [φ₃].

Again, using Snell's Law, the new angle of refraction, φ₃″, can be expressed in terms of the original angle of incidence, φ₃, as follows.

$${n}^{′} \cdot Sin [ {∅}_{3}^{′} ] = n \cdot Sin [ {∅}_{3}^{″} ] \\ Sin [ {∅}_{3}^{″} ] = \frac{{n}^{′}}{n} \cdot Sin [ {∅}_{3}^{′} ] \qquad ( 1 \text{-} 9 )$$

But, from the first refraction,

$$n \cdot Sin [ {∅}_{3} ] = {n}^{′} \cdot Sin [ {∅}_{3}^{′} ] \\ Sin [ {∅}_{3}^{′} ] = \frac{n}{{n}^{′}} \cdot Sin [ {∅}_{3} ] \qquad ( 1 \text{-} 10 )$$

so that, substituting equation (1-10) into equation (1-9), the result, equation (1-11), is that the final angle of refraction equals the initial angle of incidence. It is exactly as if the incident ray were reflected from the boundary surface.

$$\begin{matrix}Sin [ {∅}_{3}^{″} ] = \frac{{n}^{′}}{n} \cdot Sin [ {∅}_{3}^{′} ] \frac{{n}^{′}}{n} \cdot [ \frac{n}{{n}^{′}} \cdot Sin [ {∅}_{3} ] ] \\ = Sin [ {∅}_{3} ] \\ {∅}_{3}^{″} = {∅}_{3}\end{matrix} \qquad ( 1 \text{-} 11 )$$

So long as the angle of incidence is greater than the critical angle, the purely speed dependent process of refraction produces the same result, for light, as if a perfect reflection were taking place. “Normal” reflecting is essentially always partial and in optics one speaks of the amount of reflection, the “reflectivity”, of a surface. This 100% “reflecting” of light is most useful when done in a system with ninety degree right prisms.

Such prisms are a solid having a triangular cross section. A right prism has its third side perpendicular to that cross section. A ninety degree right prism is one having for its cross section an isosceles right triangle (one having the angles 90°-45°-45°). Recalling equation (1-8), above, for the critical angle of refraction, a suitable ninety degree right prism is one having its critical angle in air and in free space less than 45°.

That is not a difficult requirement. Glass, even taken at its smallest index of refraction, 1.46, has such a critical angle in air and in free space.

$$\begin{matrix}Sin [ {∅}_{critical} ] = \frac{{n}^{′}}{n} \\ = \frac{1.00029}{1.46} \\ = 0.68 … \\ {∅}_{critical} \approx 43 ° < 45 °\end{matrix} \qquad ( 1 \text{-} 12 )$$

When the angle of incidence is greater than the critical angle the refraction at the boundary surface is back into the original surface. The final angle of refraction is equal to the initial angle of incidence. The appearance is as if the incident propagation reflected from the boundary surface, departing at an angle identical to the angle of incidence.

A ninety degree right prism with the incoming propagation incident on the hypotenuse of the triangular cross section at a 45° angle of incidence reflects that propagation at another 45° angle producing a total direction change of 90°. With the incoming propagation incident on a leg of the triangular cross section the propagation is re-directed to the opposite direction by two successive reflections. These effects are illustrated in Drawing 1-4.

Diffraction

Optical diffraction, Drawing 1-5a, is the bending of light at an edge of an opaque material as at the two edges of a slit.

Light diffraction produces interference patterns, Drawing 1-5b. It is to those that principal attention is paid in physics analyses of diffraction. The interference patterns are analyzed in terms of Huygens's Principle.

Huygens′ Principle which can be useful in constructing the propagation of a wave front through a changing environment is as follows.

Every point of a wave front may be considered the source of minute wavelets that propagate outward in all directions from that point at the speed of propagation in the substance(s) encountered in each particular direction. The new wave front after any time is the surface tangent to the wavelets at that time (taking account of the general direction of propagation). See Drawing 1-6.

Huygens's Principle is not a description of the actual behavior of wave propagation. Each point on a light wave front does not propagate outward in all directions. It propagates in whatever direction the U-waves, that carry it as a modulatory imprint, are themselves traveling.

If that were not the case focusing of light would be severely impaired for the initial result of the focusing would be quickly blurred by the spreading out of the light of each “wavelet”. In fact, experience shows that that does not happen. Focused beams of light such as searchlights and laser light beams stay mostly focused (except for a small amount of dispersion caused by dust or fog in the air).

Light propagation is in straight lines outward from its source until that direction is changed as by reflection, refraction, diffraction or any change in the direction of the U-waves carrying it. The diffraction effect in Drawing 1-5a is due solely to change in the direction of the light-carrying U-waves.

The diffraction effect occurs with other wave forms such as sound and water waves. The diffraction of sound and of water waves is a different phenomenon from diffraction of light. Sound and water waves are longitudinal oscillations consisting of a variation in the pressure and velocity of individual particles [atoms and molecules] in the air or water, an oscillatory compression-decompression. They propagate without spreading only when surrounded on all sides of their direction of propagation in their medium of propagation, air or water, by like waves propagating in the same direction. At a slit or an edge that condition is removed so that the waves spread into the unoccupied region adjacent to the propagating sound or water waves.

Light, x-rays and other such propagations are a transverse oscillation of electric and magnetic fields expressed as a modulation of the underlying U-waves, which are a continuous, non-particulate flow of medium, carrying the electromagnetic fields. They propagate in the direction of the U-waves carrying them independently of conditions along side their path unless those conditions affect their underlying U-waves as in diffraction. [In refraction the direction change is due to both electromagnetic interaction and U-wave slowing.]

Reflection

Light incident on a reflecting surface is absorbed and re-radiated in the reflective direction, that direction being mandated by conservation of the linear momentum in the incident light so that the reflection is at the same angle of incidence as that of the arriving waves. Not all surfaces support reflection. Non-reflecting surfaces absorb the light but do not re-radiate it, at least not as light. Of course, most surfaces are partially reflective and partially absorptive.

Interference

When two light waves not in phase pass through each other a pattern of maxima and minima results as, for example, in Drawing 1-5b, above. The instantaneous observed amplitude at any point is the sum of the individual amplitudes of the two interfering wave trains.

Polarization

Light, oscillates in a plane perpendicular to the direction of propagation. The electric and magnetic fields of light oscillate at right angles to each other in that plane. The orientation of those two fields' oscillations corresponds to the polarization of the light.

### Section 2—Analysis of Gravitics Behavior

### U-Waves

U-wave propagation is basically in straight lines outward from its source until encounter with other U-waves produces deflection of their direction.

Gravitation, U-Wave Flow, and the Affect of Matter

Gravitation is caused by the U-waves that encounter a center-of-oscillation producing an increase in the ambient U-wave concentration on the encountered side of the core of the encountered center. That has the effect of reducing the encountered core's speed of propagation of new medium in the direction from which the gravitation-causing U-waves came. As presented in The Origin and Its Meaning that effect creates an imbalance in the core's propagation, an imbalance that cannot exist.

As a result, to correct (or, rather, to prevent) the imbalance, the encountered core must and does take on an increment of velocity in the direction from which the gravitation-causing U-waves came. Such an increment of velocity change must take place for each cycle of arriving gravitation-causing U-wave. The result is an acceleration that is proportional to the frequency of the arriving U-waves, which frequency is itself proportional to the mass of the source center from which those U-waves came. The effect is also proportional to the amplitude of the arriving gravitational waves making it vary inversely as the square of the distance from the wave-source center.

Control over gravitation then requires controlling the U-waves that produce the gravitational effects. Therefore the natural behavior of U-wave flow must be studied. The only source of U-waves is matter and use of matter would appear to be the principal if not sole means of affecting U-wave flow.

U-Waves in Matter

The components of optics that are applicable to gravitics are those characteristic of any wave: speed—refraction—diffraction—and interference. The components of optics that depend on the transverse electromagnetic field aspect of light, and therefore do not apply to gravitics are:
reflection—polarization—and the electromagnetic aspect of refraction.

To the extent that refraction is partially applicable to gravities it can be subsumed in the general consideration of diffraction. The interference of the forward and rearward oscillations of a center-of-oscillation is fundamental to the matter waves of particles, and interference between U-waves encountering each other in free space takes place but has no significant effect. Thus the only aspects of optics that apply to gravitics are the speed of propagation and diffraction, which itself is caused by speed differences and is the principal effect of variations in propagation speed.

The speed of light, that is the speed of actual electromagnetic light, in matter is the consequence of two effects:

The speed of the U-waves on which the light is imprinted, and

Interaction of the light with the matter through which it is passing.

The speed of actual light in matter and the speed of propagation of U-waves in that same matter are different, the light being slower to the extent of delay due to its interaction with the matter. As a result, the index of refraction of actual light is of little use in analyzing U-wave behavior. What is needed is the speed of the U-waves, themselves, without light's electromagnetic effects.

As presented in The Origin and Its Meaning, U-waves may be slowed when passing through other U-waves. The mechanism that causes U-waves to slow when they pass through each other applies only to the components of their vector directions that are exactly opposite. Equation (16-36) of The Origin and Its Meaning, given below as equation (2-1), presents the amount of that slowing for the two flows' components in exactly opposite directions.

$$Flows {u}_{1} and {u}_{2} at resulting speeds {c}_{1} and {c}_{2} \\ [ a ] Each of the two flows separately \text{:} \\ Same Direction \\ {c}_{1} = c \cdot \frac{{u}_{1} ( amplitude )}{{u}_{1} ( {μ}_{0} and {ɛ}_{0} )} = c \\ {c}_{2} = c \cdot \frac{{u}_{2} ( amplitude )}{{u}_{2} ( {μ}_{0} and {ɛ}_{0} )} = c \\ Opposite Directions \\ {c}_{1} = c \cdot \frac{{u}_{1} ( amplitude )}{{u}_{1} ( {μ}_{0} and {ɛ}_{0} )} = c \\ {c}_{2} = c \cdot \frac{{u}_{2} ( amplitude )}{{u}_{2} ( {μ}_{0} and {ɛ}_{0} )} = c \\ [ b ] The two flows encountering each other \text{:} \\ Same Direction \\ {c}_{1 , 2} = c \cdot \frac{{u}_{1} ( amp ) + {u}_{2} ( amp )}{{u}_{1} ( μ , ɛ )} = c \\ Opposite Directions \\ {c}_{1} = c \cdot \frac{{u}_{1} ( amp )}{{u}_{1} ( μ , ɛ ) + {u}_{2} ( μ , ɛ ) } < “ c ” \\ {c}_{2} = c \cdot \frac{{u}_{2} ( amp )}{{u}_{1} ( μ , ɛ ) + {u}_{2} ( μ , ɛ )} < “ c ” \qquad ( 2 \text{-} 1 )$$

Such slowing depends on the relative amounts or concentrations of the opposed-direction U-wave streams, u₁ and u₂. Their amplitudes or concentrations are radially diverging, inverse-square diminishing vector quantities and cannot add in opposite directions; their permeability and dielectric constants, μ and ε, are scalar quantities that determine the speed of U-wave propagation and which combine as shown in equation (2-1) above.

For gravitics purposes the interest is in the potential for slowing of the gravitational U-wave flux flowing radially outward from the Earth by some configuration of matter at the Earth's surface. Because the amount of slowing depends on the relative amounts or concentrations of the opposed-direction U-wave streams the problem is to determine within a specified type of matter at the Earth's surface the magnitude, u₂, of the component of its ambient U-wave flow that is directly opposite to u₁, the gravitational U-wave propagation arriving from below. Then the slowing of u₁ by u₂ can be determined. That analysis is performed in Appendix A.

The result is that the U-wave gravitational flux at the Earths' surface is on the order of

u_{gravitational}=u₁≈2·10³⁵·U_{c}

compared to the ambient U-wave flow concentrations in local matter, small objects at the Earth's surface, of on the order of

u_{local ambient}=u₁≈1·10²⁰·U_{c}

so that

u_{gravitational}≈10¹⁵·u_{local ambient}

which also means that the gravitational attraction for each other [i.e. horizontally] between Earth's surface local objects is 10¹⁵ times weaker than the Earth's gravitational attraction downward that they all experience.

It would thus appear that the medium flow concentration of gravitation at the Earth's surface is so immensely greater than the ambient flow in local matter that no useful slowing of the Earth's gravitational flow can be directly effected by a modest amount of matter. Put in other terms, the index of refraction of the Earth's gravitational U-wave flow remains unchanged for practical purposes regardless of the local matter or empty space through which it passes.

Thus the direct use of natural local matter to deflect or control gravitational U-waves appears to be self-defeating. The amount of matter needed to produce a useful U-wave medium concentration would itself be an immense gravitating mass. Thus finding alternative methods of gravitational U-wave management, a way to increase the effective value of u_{local ambient} or to increase its effectiveness, is needed. That is pursued further below in this paper.

### U-Waves in Optics

Refraction

Optical refraction is the bending of light when it passes from a substance of one index of refraction [one speed of propagation] into a substance of different index of refraction [different speed of propagation]. The speed of propagation differences are effects of the behavior of light as light and the behavior of the underlying U-waves carrying the light.

Having just determined above that natural local matter is essentially unable to affect gravitational U-waves it is necessary to clarify how natural local matter nevertheless contributes significantly to the processes of optical refraction [and to diffraction]. It is because of the distinction between the immensely concentrated U-wave field that constitutes the gravitational field and the relatively minor concentration U-wave fields of local matter.

The [Earth's] gravitational U-wave field is the cumulative effect of all of the matter of the entire planet propagating U-waves directed, in net effect, radially outward [to us upward] from the planet. A local piece of matter, such as a piece of glass for example, is comprised of particles all propagating U-waves radially outward in all directions. The number of such source particles in the local piece of matter is immensely smaller than the number whose U-wave propagation makes up the gravitational U-wave field.

Light is slowed in a substance partially because its U-waves are slowed and primarily because its electric field disturbs the charges of each atom (primarily the electrons) which oscillate and radiate their own electromagnetic waves at the same frequency but with a phase delay. The result is a wave with a shorter wavelength producing a consequent slowing of the phase velocity of the wave. That slowing varies in amount with the particular light frequency involved.

The refractive bending of a light beam is the bending of the U-wave front by the matter in the refraction-causing object as illustrated in Drawings 1-1, 1-2, and 1-3 of the preceding Section 1.

Diffraction

Diffraction, the bending of light around an edge, is as illustrated in Drawing 1-5a.

U-wave propagation is in straight lines outward from its source until encounter with other U-waves produces deflection. The edges of the slit in Drawing 1-5a, above, are the boundary between the substance of the barrier in which the slit is an opening, which is some material opaque substance, and the substance of the opening, which is air or free space as the case may be.

The matter density of those two regions, the barrier and the opening, are different and the density of local U-wave propagation in them differs. That local U-wave propagation is radially outward in all directions from each particle of matter of the barrier and of the air in the slit, and some of that propagation has a component directed opposed to the U-waves carrying the incoming light.

As a result [see Drawing 2-1] there is a gradient across the slit in the amount of ambient U-wave propagation and its component directed opposed to the U-waves bringing the incoming light [from the left in Drawing 2-1]. Those opposed U-waves slow the arriving U-waves encountering the slit in varied amounts depending on where across the slit the incoming light-carrying U-waves arrive.

At the edges of the slit the U-waves are slowed more than in the middle of the slit where they are slowed less. The slit is a region of smoothly varied speed of U-wave propagation. The U-waves' wave front is consequently deflected and that deflection appears as a deflection, a diffraction, of the light carried on the U-waves. Rather than the sharp refraction at a precise boundary as in Drawings 1-1, 1-2, and 1-3, there is an, in effect, gradual refraction depending on the location of a particular light ray relative to the edge of the slit. This produces the diffraction effect depicted above.

Thus diffraction is a purely U-wave effect. The reasons for that conclusion that light diffraction is purely a U-wave phenomenon and that the affect on light is solely because the U-waves carrying the light are so differentially slowed are as follows.
The evidence of searchlight and laser light beams staying largely focused [except for minor scattering due to dust particles and fog] refutes the Huygens Principle explanation of diffraction. That principle would require dispersion of focused light beams if it were a description of behavior in material reality rather than being merely a method for determining the resultant wavefront in some cases.
Light diffraction does not involve the light traveling through media of different indexes of refraction, of different speeds of propagation, as in the case of refraction and there illustrated by the spreading of white light into its color spectrum by passing through a prism. All of the light passing a diffracting edge experiences the same index of refraction, the same speed, aside from its U-waves being differentially slowed.
Light passing through a material, such as glass as in refraction, interacts electromagnetically with the atomic electrons in the material. But in the case of light diffraction the slit edge is opaque and light travel through it is not applicable. In light diffraction there is no significant electromagnetic interaction with the material's electrons.
[In x-ray diffraction the x-rays do pass through the material and the diffractive effect is due to both U-wave slowing as in light diffraction and to electromagnetic slowing as in light refraction.]
The frequency dependence in diffraction, that which produces the interference pattern, is only due to the light riding on the U-waves traveling different distances on U-waves passing through different locations across the slit width, and different distances traveled produce different phases of the light arriving at any particular point.
In light diffraction the deflecting of the incoming rays is a smooth fan-shaped spread overall [as shown in Section 3 and the Cauchy-Lorentz distribution]. But the slowing of each individual ray varies in oscillatory fashion according to the oscillatory form of the encountered U-waves that cause the slowing. Therefore the amount of deflection of each ray oscillates. That has the effect of each ray appearing to propagate in a Huygen's Principle manner: not in all available directions at the same time, but overall directed in a range of available directions.
The diffraction of sound and of water waves is a different phenomenon from diffraction of light. Sound and water waves are longitudinal oscillations in their air and water. They consist of variation in the pressure a result of variation in the velocity and density of individual particles [atoms and molecules] in the air or water, an oscillatory longitudinal compression-decompression. They propagate without spreading only when surrounded on all sides of their direction of propagation in their medium of propagation, air or water, by synchronized like waves propagating in the same direction. At a slit or an edge that condition is removed so that the waves spread into the unoccupied region adjacent to the propagating sound or water waves.

Thus the only undisposed-of available cause of the light ray bending in light diffraction is U-wave deflection due to differential U-wave slowing.

[The classical treatment of diffraction, unaware of light as an imprint on the U-waves carrying it, vaguely attributes the spreading of the light on the far side of the slit to the operation of Huygen's Principle and light's electromagnetic field, and concentrates its attention on the interference patterns that appear in light diffraction depending on the wavelength of the light relative to the width of the slit.]

### Gravitational U-Wave Management Methods

Gravitational U-wave management requires controlling the amount of U-waves or their direction of propagation. The amount is determined solely by the amount of matter and any benefit from that form of control is more than offset by the disadvantage of the major amount of additional matter required to produce an effect. The remaining aspect of the problem is how to manage the direction of U-wave propagation.

Prism Deflecting

Prism deflecting of light waves is illustrated in Drawing 1-4, and analyzed in the preceding Drawing 1-3 and its subsequent discussion. The benefit of this method would be that 100% reflection or deflection, as desired, would be obtained and those could be readily continuously varied in effectiveness over the range of 0% to 100%.

The problem with this method is that a practical implementation that so operates on U-waves, as compared to how it operates on a light imprint on them, appears to be quite difficult. As already developed earlier above for a useful interaction of matter and gravitational field to take place it would be necessary to have matter with on the order of 10¹⁵ times more ambient U-wave flow.

Equation (2-2) below results directly from the above equations (1-3), the definition of the index of refraction, and equation (1-12) and its development.

$$\frac{Velocity Within Prism}{Velocity Abo ve Prism} = \frac{v}{{v}^{′}} = \frac{v}{c} < Sin [ 45 ° ] = 0.707 \\ Velocity Within Prism = v < 0.707 \cdot c \qquad ( 2 \text{-} 2 )$$

In this application, the velocity above the prism is c, the natural U-wave velocity. Therefore, to obtain this prism reflection the U-wave propagation velocity within the prism must be reduced to less than 0. 707·c, that fraction of its normal velocity. Uniform slowing of U-waves in the amount here required would, pending further developments, appear to be impossible.

X-Ray Focusing

One of the problems in using reflection or refraction to manage the direction of U-waves is that U-waves naturally penetrate and permeate all matter. To the flow of the U-waves it as if the potential reflecting or refracting matter does not exist; it is essentially ignored.

A more familiar case of that kind of problem is that of focusing x-rays, which, because of their much greater energy and their wavelength much shorter than light, fairly readily penetrate most materials unless the material is present in significant thicknesses. Thus the case of x-rays is somewhat intermediate between that of easily managed light and difficult-to-manage U-waves.

The problem of x-ray focusing has been solved and the solution is used in spacecraft designed to function as x-ray telescopes for astronomical investigations in the x-ray spectrum of the cosmos. The most successful of those is the spacecraft named Chandra. It uses an x-ray focusing system known as Wolter I [after the developer of the technology].

X-ray telescopes must be very different from optical ones. X-ray photons penetrate into a mirror in much the same way that bullets slam into a wall. Likewise, just as bullets ricochet when they hit a wall at a grazing angle, so too will X-rays ricochet off mirrors. The mirrors have to be exquisitely shaped and aligned nearly parallel to incoming X-rays. Thus they look more like barrels than the familiar dish shape of optical telescopes. A diagram of the Chandra X-ray Telescope appears in Drawing 2-2.

However, even this “grazing incidence” type of propagation direction control will not work for U-waves. Just as the wavelength of x-rays is much smaller than that of light, so that of U-waves is much smaller than that of x-rays.

TABLE 2-3
Light vs. X-Rays vs. U-Waves Comparison

| Parameter | Light | X-Rays | U-Waves |
|---|---|---|---|
| Typical Frequency | 10¹⁵ herz [cps] | 10¹⁹ herz [cps] | 10²³ herz [cps] |
| Typical Wavelength | 3 · 10⁻⁷ m | 3 · 10⁻¹¹ m | 3 · 10⁻¹⁵ m |

Slit Focusing

A solution to the problem might be “slit focusing”, using the diffraction effect of light encountering a slit. The light phenomenon is illustrated in the earlier above Drawings 1-5 and 1-7.

As discussed above with the original Drawing 1-7, this phenomenon is entirely a U-wave effect. That is, the diffraction is not due to the light being absorbed and then re-radiated, as is the case with reflection of light, nor to Huygens's Principle “wavelets”. The diffraction of the light is due to the U-wave wave front being deflected because the U-waves in the middle of the slit propagate at a faster speed than those near the edge, that being due to the difference in the ambient U-wave densities in the two regions.

Thus significant U-wave deflection can be obtained where the U-waves pass close to an “edge”. While a step in the direction of practical control over gravitation, that is a long way from a functioning practical system. The problem is that the nearness to the “edge” must be not more than on the order of 10-7 meters for even a moderate amount of deflection of Earth's surface local ambient U-waves, and those are 10¹⁵ times weaker than Earth's gravitational U-waves.

X-ray Crystallography

Extensive research has been done in the field of using crystalline forms of matter to diffract x-rays. That field is termed x-ray crystallography and its main purpose is the study of the form and structure of various crystalline forms. Analysis of the diffraction patterns resulting from passing an x-ray beam through the crystal can provide substantial information on the atomic structure within the crystal.

This has been developed to the point where it is now possible to create crystalline forms of organic compounds, such as proteins, and to develop understanding of the organic compound's structure from analysis of its diffraction patterns.

For the present purpose the significance of x-ray crystallography is that it demonstrates the scattering of the x-ray beam by the crystal structure, a different form of diffraction pattern from the form produced by a slit. But, the use of scattering of the U-wave gravitational flux could be expected to effectively reduce the portion of that flux producing gravitational action on objects directly above the crystal.

Crystal Deflecting

Thus a candidate for objects to cause diffraction of U-waves to achieve U-wave deflecting is the atoms in the uniform lattice of a crystal. Inter-atomic spacings for this purpose in a cubic crystal lattice are on the order of about 3·10⁻¹⁰ meters, nearly 1000 times closer than the 10⁻⁷ meter width requirement for the slit earlier above.

In a cubic crystal lattice most U-wave rays pass far from its atoms. But, if the crystal is appropriately tilted relative to the vertical as in Drawing 2-4 every arriving vertically directed U-wave ray could be forced to pass close to an atom.

The objective here is to make use of the fact that the U-waves of interest, the U-wave gravitational flux, consists purely of rays that are directed radially outward from the Earth's surface so that locally the flux is purely parallel vertically upward rays. By tilting the repetitive regular structure of the cubic crystal it can be arranged that all of the rays of the gravitational U-wave flux pass close to atoms of the cubic crystal. The tilt operates dominantly on such vertical rays and has relatively little effect on other U-wave propagation.

The tilt creates an effective [for vertical U-wave rays] decrease in the interatomic spacing of the atoms in the cubic crystal lattice. For example, those atoms are uniformly spaced, typically at a little over 10⁻¹⁰ meter apart. If the tilted cubic crystal were 1 centimeter thick, it would have 10⁸ layers of atoms. Then the tilting of the cubic crystal orientation, as indicated in the above Drawing 2-4, could provide an atomic spacing effective on vertically oriented rays of about 10⁻¹⁸ meter, as compared to the crystal's natural spacing of about 10⁻¹⁰ meter or about 10¹¹ times closer than the 10⁻⁷ meter upper limit on spacing from the earlier case of a slit.

A measure of the relative deflection producing power is the Mean Free Path for rays of U-wave propagation in the tilted cubic crystal deflector as compared to the mean free path experienced by those same rays as they pass through the Earth's layers in their outward, gravitation-producing, paths.

The mean free path is determined by imagining U-wave rays directed toward an infinitesimally thin slab of material containing spaced individual, identical atom “targets”, the slab being of thickness dx and width and height L. The total area of the slab face is L². The U-wave ray interception area presented by the targets is the number of targets times their individual common cross sectional area, A. The number of targets is their concentration per unit volume, C, times the volume of the slab, L²·dx.

Letting the density of the incoming U-waves be D, we seek the reduction in that density, dD, as it travels distance dx through the target-bearing slab. The fractional rate of target encounters in that travel is the interception area presented by the targets divided by the total area of the slab.

$$\begin{matrix}Rate = \frac{Targets Interception Area}{Total Slab Area} \\ = \frac{C \cdot [ {L}^{2} \cdot d x ] \cdot A}{{L}^{2}} \\ = C \cdot A \cdot d x\end{matrix} \qquad ( 2 \text{-} 3 )$$

The reduction, dD, in the density, D, of the incoming U-waves, because of their passing through the slab, is the original arriving density times that above fractional Rate of reduction. The result is a typical decaying exponential for which the decay constant is, in this case, the Mean Free Path or MFP as follows.

$$\begin{matrix}\begin{matrix}d D = - \{ D \cdot Rate \} \\ = - \{ D \cdot [ C \cdot A \cdot d x ] \}\end{matrix} & ( 2 \text{-} 4 ) \\ \begin{matrix}\frac{d D}{d x} = - D \cdot C \cdot A \\ D = {D}_{0} \cdot ɛ - C \cdot A \cdot x \\ D = {D}_{0} \cdot {ɛ}^{- [ x / MFP ]} \\ [ MFP = 1 / C \cdot A ]\end{matrix} & ( 2 \text{-} 4 , continued )\end{matrix}$$

Therefore the mean free path is

$$\begin{matrix}MFP = 1 / C \cdot A \\ = \frac{1}{\begin{matrix}[ C = Atoms Per Unit Volume ] \cdot \\ [ A = Atom Cross Section Area ]\end{matrix}}\end{matrix} \qquad ( 2 \text{-} 5 )$$

For the Earth the concentration of atoms is on the order of C=5·10²⁸ per cubic meter. In the cubic crystal deflector that has just been suggested the target spacing achieved by the tilt is 10⁻¹⁸ meters. Each such target has cross sectional area space available to it equal to a circle of that diameter so that

A=π/4·[10⁻¹⁸]²8·10⁻³⁷ meter² (2-6)

and, for targets as fine as those in the cubic crystal deflector, the mean free path in the Earth's outer layers is

MFP=2.5·10⁷ meters (2-7)

as compared to the corresponding mean free path in the 1 centimeter thick cubic crystal deflector slab of 1 centimeter or about 10⁹ times shorter.

Referring again to the inset box sub-drawing at the left side of Drawing 2-4 depending on how close they pass to the deflecting atom different rays of U-waves will be deflected different amounts. [The sub drawing should be considered as if viewed from above and rotated around the vertical through a full 360°.]

Rather than the ideally preferred 180° deflection of all rays so that they are returned toward their source, the effect of the cubic crystal deflector is to scatter the rays in many directions but to generally reduce the net number exiting above the deflector and still directed vertically upward. Other than in the specifically vertical orientation of the slightly tilted crystal the general mean free path in the crystal is on the order of 10⁹ meters [over 1,000,000 miles]. Thus most of the scattered rays of U-waves should exit the deflector without further interaction.

The cubic crystal deflector should produce major, reduction in the gravitational action on whatever is above it, but it should not necessarily succeed in totally removing that action.

Here the applicable focusing process is the “Coulomb Focusing” analyzed in the book The Origin and Its Meaning [see Section 1], treating the focusing action of a particle nucleus on incoming U-waves. The details are in Section 16 of the book, beginning at page 247. There the attention is on that portion of incoming U-waves that is focused onto the center of the encountered center-of-oscillation [particle]. Now the attention must be on the remaining portion of those incoming U-waves, that part which “misses” the encountered center.

The situation is broadly analogous to a ray of light from a far distant galaxy passing by and near to a less distant galaxy which gravitationally deflects the light beam. Now the deflected light is incoming U-waves with their gravitational effect and now the deflection is the desired management of the incoming gravitation-causing U-waves. And, of course, now the dimensions involved are many orders of magnitude smaller than are those of the inter-galactic case.

The problem now is to quantify the deflection of those U-waves. The next following Section 3 presents detailed calculations for U-wave deflection at a slit.

Section 4 then applies those results to analysis of a cubic crystal to function as a U-wave deflector based on the above concept.

Focused Deflecting Considerations

In general U-waves, including their gravitational effect, cannot be focused. In order to focus with a lens type device it must be possible to design it so that the slowing of the wave front caused by the lens follows a specific intended pattern, for example a spherical convex lens. But, the only such pattern available to apply to U-waves is the inverse square variation of U-wave intensity with distance from the wave source.

In order to focus with a mirror type device, it being possible to shape a mirror to a specific intended pattern, U-waves would have to reflect. But, U-waves cannot reflect. Reflection occurs when the electromagnetic [light] modulation on the U-wave stream transfers to atoms of the reflecting surface which then immediately re-radiate the light with conservation of momentum resulting in equal angles of incidence and reflection. The U-wave stream itself is not reflected.

Diffraction of U-waves produces a quasi-focusing effect, but its shape or pattern is negligibly controllable and the output focuses at different focal points so that the output image is blurred. Drawing 2-6 illustrates this for an atom of the cubic crystal lattice.

The effect in Drawing 2-6 is not real focusing because different rays are directed to different “focal points”. What it really illustrates is the scattering away from the pure vertical that the cubic crystal deflector produces.

The only known instance of apparently focused U-waves is the effect of a large cosmic mass located between we observers and a second, more distant, cosmic light source object, an effect termed “gravitational lensing” and more or less equivalent to a convex lens in effect. The arrangement is the same as in the above Drawing 2-6 except for a vast difference in scale.

However, gravitational lensing focuses different rays on to different focal points as in Drawing 2-6. In practice, when such an effect is observed with astronomical telescopes, the observer is at only a single focal point and observes only a narrow range of focal points resulting in the appearance of a somewhat “focused” image.

Section 3—U-Wave Diffractive Path Bending

### U-Wave Deflection Caused By U-Wave Slowing

The bending of U-waves' paths results from differential slowing, that is the systematic slowing of the U-wave wave front in different amounts along that front. The slowing takes place in accordance with equation (2-1), above. Drawing 3-1 depicts the differential slowing-caused process.

The Drawing indicates the differential slowing of the upward-directed [as for gravitation] U-wave flux that results in deflection of the U-waves' paths. The slowing is directly proportional to the encountered concentration of the opposed-direction U-wave flux, and, therefore the angle of deflection, Φ, is proportional to that concentration.

### Quantifying the U-Wave Deflection in Light Diffraction

The only precise, well documented instance of U-wave deflection is diffraction of light at a slit. X-ray diffraction analysis is too focused on its objective of interpreting particular specific crystal structure. Astronomical gravitational lens cases are likewise too focused on the result, observation of distant cosmic objects, not the method.

Drawing 3-2 presents the diffraction pattern produced by a slit that is 5.4·10⁻⁶ meter wide with incoming light of wavelength 4.13·10⁻⁷ meter². The peaks and valleys of the pattern, the interference pattern, are a phenomenon of the light imprint on the U-waves that carry it. The envelope of the pattern is the relative amounts of the underlying U-waves carrying the light.

For that same reason, while the interference pattern varies according to the wavelength of the light involved, the envelope of that pattern is always the same [for the same slit] because it depends not on the light wavelength but on the U-wave slowing-bending effect of Drawing 3-1 as implemented by the atoms of the edges of the slit.

The diffraction pattern is a projection on a screen or piece of photographic film of the diffracted light as it spreads out due to the diffracting action. The physical size, the linear dimension of the pattern becomes larger as the distance from the diffracting slit to the screen or film on which the pattern appears increases. But the angles, as measured from the center of the slit to any point on the diffraction pattern [relative to the 0° angle from the center of the slit to the center of the pattern], are the same regardless of the distance from the slit to the screen or film.

Therefore, to analyze and evaluate the pattern requires attending to those angles, not linear distances on the pattern. Since the linear distances on the pattern are irrelevant, any convenient distance from the slit to the screen or film may be chosen. In the following analysis that distance will be taken as equal to the slit width, 5.4·10⁻⁶ meter in this case.

The data of interest here, which is a measure of the amount of U-wave bending contained in the diffraction pattern, is the portion of the total light incident on the slit appearing in any specified portion of the diffraction pattern. That portion can be defined in terms of the angles just described and that portion is an otherwise dimensionless number, again independent of the physical or linear size of the diffraction pattern.

The U-wave concentration produced by each of the two slit edges falls off with distance from the edge inversely as the square of distance from its atoms. The Cauchy-Lorentz Distribution³ as in Drawing 3-3 is likewise an inverse square function of its variable. As the Drawing indicates the Cauchy-Lorentz distribution's Density Function can represent the relative U-wave intensity pattern produced by the diffraction process by representing the envelope of the diffraction pattern, which envelope is the relative U-wave concentrations in the pattern. In Drawing 3-3, the Cauchy-Lorentz distribution is fitted to the diffraction pattern by the appropriate choice of value of the distribution parameter γ [Greek gamma]. [3] http://en.wikipedia.org/wiki/Cauchy distribution

The Cauchy-Lorentz Distribution for this application is follows.

$$The Cauchy \text{-} Lorentz Distribution Density Function \\ [ a ] In General \\ f ( x ; {x}_{0} , γ ) = \frac{1}{π} \cdot [ \frac{γ}{{( x - {x}_{0} )}^{2} + {γ}^{2}} ] \\ [ b ] As Used Here \\ f ( d ; mid , γ ) = [ \frac{γ}{{( d - mid )}^{2} + {γ}^{2}} ] \\ mid = half \text{-} way point between slit edges \\ d = distance from mid \\ γ = half \text{-} width at half \text{-} maximum \qquad ( 3 \text{-} 1 )$$

From Drawing 3-3, the half-width of the Cauchy-Lorentz Distribution at its half-maximum is 74.0% of the distance from the mid-point to the first minimum in the interference pattern. That is γ is 74.0% of the displacement from the centerline to the first intensity minimum outward from the centerline. Calculating the deflection angle to that minimum⁴ the angle is found to be 4.39°. [4] http://hyperphysics.phy-astr.gsu .edu/hbase/phyopt/sinslit.html#c1

The corresponding displacement along the d-axis [for screen distance=slit width] of the above Drawing 3-3 is the value of γ in the formulation of the Cauchy-Lorentz distribution.

$$\begin{matrix}γ = [ 74 \% of ] [ [ slit width ] \cdot Tan [ 4.39 ° ] ] \\ = [ 0.74 ] \cdot [ 5.4 \cdot {10}^{- 6} meter ] \cdot [ 0.077 ] \\ = 3.1 \cdot {10}^{- 7} meter\end{matrix} \qquad ( 3 \text{-} 2 )$$

The deflection angle, θ, for any particular point on the diffraction pattern is the angle between [a] a reference line that runs from the center of the slit perpendicular to the barrier containing the slit toward the projected diffraction pattern and [b] a line running from the center of the slit to the location of the particular point on the zero-intensity abscissa of the diffraction pattern. That is the angle of deflection of the rays directed to that point and of intensity per the Cauchy-Lorentz Distribution at that point. In these diffraction patterns so long as the ratio of the wavelength of the incident light to the width of the slit is constant, then each deflection angle, θ, is independent of the distance from the slit to the screen where the diffraction pattern is projected.

The interest here is not in the location of the light interference maxima and minima, but in the various deflection angles the diffraction imposes on the U-waves. However, calculation of the deflection angles to the minima provides a good indication of the amount of U-wave deflection obtained over the overall diffraction pattern. Table 3-4, below, presents that data for the 5.4·10⁻⁶ meter wide slit with incoming light of wavelength 4.13·10⁻⁷ meter. [The minimums are counted outward from the center peak of the diffraction interference pattern].

TABLE 3-4
Some U-wave Deflection Angles

| Minimum # | ⊖° |
|---|---|
| 1 | 4.39 |
| 2 | 8.80 |
| 3 | 13.26 |
| 4 | 17.81 |
| 5 | 22.48 |
| 6 | 27.36 |
| 7 | 32.37 |
| 8 | 37.72 |
| 9 | 43.50 |
| 10 | 49.89 |
| 11 | 57.28 |
| 12 | 66.60 |
| 13 | 83.86 |
| 14 | [n/a > 90°] |

The fourth minimum outward to either side from the central peak of the diffraction pattern in Drawing 3-2 corresponds to Minimum #4 in the above table. Therefore, the maximum U-wave deflection angle depicted in Drawing 3-2 and 3-3 is about θ=±17.8° at which point the U-wave intensity is about 10% of the peak. Of course, the diffraction pattern extends in both directions far beyond the range shown in those Drawings and at progressively further reduced intensity and greater angle of deflection.

The Cauchy-Lorentz Distribution's Cumulative Distribution Function is the integral of the Density Function, that is the area under the Density Function curve, the cumulative density. That function is given in equation (3-3), below.

$$The Cauchy \text{-} Lorentz Distribution Cumulative Distribution Function \\ [ a ] In General \\ {f}_{cum } ( x ; {x}_{0} , γ ) = \frac{1}{π} \cdot arctan [ \frac{x - {x}_{0}}{γ} ] + \frac{1}{2} \\ [ b ] As Used Here \\ {f}_{cum} ( d ; mid , γ ) = \frac{1}{π} \cdot arctan [ \frac{d - mid}{γ} ] + \frac{1}{2} \qquad ( 3 \text{-} 3 )$$

With mid=0, when d=∞ [a deflection of 90° to the left in Drawing 3-3], then f_{cum}=0. Likewise at d=+∞ then f_{cum}=1, the total amount. To find the fraction, F, of the total amount of the incident light entering the slit that is deflected through some chosen angle, θ, or more to the left of mid the procedure is as follows, taking θ=−45° as an example and using γ=3.1·10⁻⁷ meter per equation (3-2). Because that light exists only on the U-waves carrying it the portion, F, is the fraction of the total amount of U-waves entering the slit that are deflected through angle θ or more.

1—Calculate the displacement, d, of Drawing 3-3.

$$\begin{matrix}d = Tan [ θ ] \times [ slit width ] \\ = Tan [ - 45 ° ] \times [ 5.4 \cdot {10}^{- 6} ] \\ = - 5.4 \cdot {10}^{- 6} [ for this example of θ = - 45 ° ]\end{matrix} \qquad ( 3 \text{-4} )$$

2—Calculate F=f_{cum}(d; mid, γ) from equation (3-3).

$$\begin{matrix}F = {f}_{cum} ( d ; mid , γ ) \\ = \frac{1}{π} \cdot arctan [ \frac{d - mid}{γ} ] + \frac{1}{2} \\ = \frac{1}{π} \cdot arctan [ \frac{( - 5.4 \cdot {10}^{- 6} ) - ( 0 )}{3.1 \cdot {10}^{- 7}} ] + \frac{1}{2} \\ = 0.018\end{matrix} \qquad ( 3 \text{-} 5 )$$

Then P, the percentage deflected through angle θ or more of the total U-waves incident on the slit is, F÷f_{cum}(d=+∞)=F÷1=F.

P=1.8% of total incident light entering the slit on each side [for this example].

In this example the portion of the total U-wave flux that is deflected by θ=45° or more is P₄₅=1.8+1.8=3.6%.

Tables 3-6, below, presents the portion of the total amount of the incoming gravitational U-wave flux that is deflected through some chosen angle, θ or more, using the above 45° example type of calculations for each of the deflection angles cited in Table 3-4, above.

TABLE 3-6
Percent of U-wave Total Deflected By Various
Angles of Deflection, ⊖, or More

| ⊖° | % Deflected |
|---|---|
| 4.39 | 40.9 |
| 8.80 | 22.6 |
| 13.26 | 15.2 |
| 17.81 | 11.3 |
| 22.48 | 8.8 |
| 27.36 | 7.1 |
| 32.37 | 5.7 |
| 37.72 | 4.7 |
| 43.50 | 3.8 |
| 49.89 | 3.1 |
| 57.28 | 2.3 |
| 66.60 | 1.6 |
| 83.86 | 0.4 |

### Using These Slit Diffraction Results for a Gravitation Deflector

The above table and example indicate that significant U-wave ray deflection does take place in the case of the atoms along the edge of the 5.4·10⁻⁶ meter wide slit, but the amount of deflection is not very much—about only 3.6% deflected 45° or more, in the example.

On the other hand, looking at 100% of the rays of U-wave flux that arrive, uniformly spaced, at the 5.4·10⁻⁶ meter wide slit, 3.6% of them arrived at that slit near enough to the atoms of one of the edges so as to be deflected 45° or more. All of the rays of that 3.6% achieved that much deflection because they passed their deflecting atom much more closely than the rest of the rays.

The 1.8% on each side of the Cauchy-Lorentz Distribution passed its deflecting atom within a distance of 1.8% of the slit width [0.018×(5.4·10⁻⁶)=9.7·10⁻⁸ meter]. If it could be arranged that all of the vertically upward U-wave gravitational flux were to pass that closely to atom then 100% of the gravitational flux would be deflected by 45° or more.

However, these deflection calculations are for a U-wave flux of the density or concentration of the U-wave flow carrying the beam of light to the diffracting slit. The vertically upward U-wave flux of the Earth's gravitational field is immensely more dense or concentrated.

[2] S. Kiselev and Tanya Yanovsky-Kiselev, Single Slit Diffraction, http://www.physics.uoguelph.ca/applets/Intro_physics/kisalev/java/slitdiffr/index.html.

Section 4—Analysis of a Cubic Crystal Gravitation

### Deflector

### A Cubic Crystal Deflector

A cubic crystal employed to deflect vertically upward flowing gravitational U-waves is briefly presented in conjunction with Drawing 2-4. The conclusion of the just prior Section 3 implies that if it could be arranged that all of the vertically upward U-wave gravitational flux were to pass sufficiently close [9.7·10⁻⁸ meter] to an atom of the cubic crystal lattice, then 100% of the gravitational flux should be deflected by 45° or more.

With proper design of the cubic crystal deflector and proper spacing of the deflector relative to an object above it, it should be possible to deflect away from the object most if not all of the gravitation that would otherwise be incident upon it. That would render the object as having significantly reduced weight or no weight at all—levitated.

A small portion of a Silicon cubic crystal is depicted in Drawing 4-1.

In the Silicon cubic crystal the edge of the cube, a, is 5.4·10⁻¹⁰ meters. From the above Drawing 4-1, the effective horizontal interatomic spacing for vertically upward traveling U-waves is half the edge, a/2=2.7·10⁻¹⁰ meters. From the Drawing the vertical layer thickness is a=5.4·10⁻¹⁰.

The edges of the slit that produces the light diffraction pattern of Drawings 3-2 and 3-3 on which the Section 3 analysis of U-wave deflection is based consist of atoms spaced along the slit edge at an interatomic spacing that is essentially the same as a cubic crystal's interatomic spacing, about 2.7·10⁻¹⁰ meter. The only difference between the light diffraction 5.4·10⁻⁶ meter wide slit and a cubic crystal's interatomic spacing is that in the cubic crystal the “slit” width is that same interatomic spacing, about 2.7·10⁻¹⁰ meter.

The diffraction pattern of Drawings 3-2 and 3-3 is determined by the edges of the slit. The edges are the limit of the “slice” of incident light that passes through the slit and the light at those edges is the most deflected because it is the nearest to the deflecting atoms of the slit edge. Similarly, the edges jointly define the mid point of the diffraction pattern which is where the action of the two edges are equally strong so that their deflecting effects cancel each other to no net deflection.

In the cubic crystal those defining points are only 2.7·10⁻¹⁰ meter apart as compared to 5.4·10⁻⁶ meter apart in the case of the slit. The calculations of equations 3-4 and 3-5 must be re-calculated for that 2.7·10⁻¹⁰ meter slit. That requires evaluating γ for its Cauchy-Lorentz Distribution. That is the same as in equation 3-2 except that the value of the slit width is changed to 2.7·10⁻¹⁰ meter. The result is equation (3-2′).

$$\begin{matrix}{γ}^{′} = [ 74 \% of ] [ [ slit width ] \cdot Tan [ 4.39 ° ] ] \\ = [ 0.74 ] \cdot [ 2.7 \cdot {10}^{- 10} meter ] \cdot [ 0.077 ] \\ = 1.5 \cdot {10}^{- 11} meter\end{matrix} \qquad ( 3 {\text{-2}}^{′} )$$

Calculating the portion, P, of the total amount of the incident U-waves entering that slit that is deflected through θ=−45° to the left of the mid point of the diffraction pattern and its Cauchy-Lorentz Distribution using γ=1.5·10⁻¹¹ meter per equation (3-2′) is as follows.

1—Calculate the displacement, d, of Drawing 3-3.

$$\begin{matrix}d = Tan [ θ ] \times [ slit width ] \\ = Tan [ - 45 ° ] \times [ 2.7 \cdot {10}^{- 10} ] \\ = - 2.7 \cdot {10}^{- 10} [ for this example of θ = - 45 ° ]\end{matrix} \qquad ( 3 \text{-} {4}^{′} )$$

2—Calculate P=f_{cum}(d; mid, γ) from equation (3-3).

$$\begin{matrix}P = {f}_{cum} ( d ; mid , γ ) \\ = \frac{1}{π} \cdot arctan [ \frac{d - mid}{γ} ] + \frac{1}{2} \\ = \frac{1}{π} \cdot arctan [ \frac{( - 2.7 \cdot {10}^{- 10} ) - ( 0 )}{1.5 \cdot {10}^{- 11}} ] + \frac{1}{2} \\ = 0.018\end{matrix} \qquad ( 3 {\text{-5}}^{′} )$$

Again the portion of the total U-wave flux that is deflected by θ=45° or more is P₄₅=1.8%+1.8%=3.6%. The result is unchanged from that in the case of the 5.4·10⁻⁶ meter slit. The reason for that is that the parameters of the Cauchy-Lorentz Distribution describing the deflected U-wave amounts in the various directions of deflection are determined by the two opposed slit edges. Contracting their spacing correspondingly contracts the distribution.

Now for the 1.8% on each side of the Cauchy-Lorentz Distribution to pass its deflecting atom within a distance equal to 1.8% of the slit width, the new value of that distance is the value for the cubic crystal slit, [0.018×(2.7·10⁻¹⁰)=4.9·10⁻¹² meter]. If it could be arranged that all of the vertically upward U-wave gravitational flux were to pass within that close a distance of an atom of the cubic crystal lattice, then 100% of the gravitational flux should be deflected by 45° or more.

### Earth's Overall Gravitation vs. a Surface Light Source

However the light-and-slit analysis deflections and calculations in Section 3 were for light traveling in the U-wave flux density generated by the Earth surface light source not the much more concentrated Earth overall gravitational U-wave outward flux. The deflections and calculations for diffraction of light as developed in Section 3 must be adjusted to compete at the level of Earth gravitational U-wave flux rather than at that of an Earth surface light source if there is to be a noticeable deflecting affect on Earth gravitation.

The U-wave flux of interest, that is that involved in the light-and-slit diffraction effects, is that flowing in the same direction as the beam of light that is diffracted at the slit. That flux derives partly from the ambient air [the flux if the light source were removed] and partly from the light source. At the slit the two are inter-mixed and the diffracting action deflects all U-waves indiscriminately, not the light U-waves selectively.

The ratio of the Earth's surface gravitational acceleration, 9. 8 m/sec², to, from Table A-8, the gravitational acceleration of air, 4.81×10⁻¹⁷ m/sec², is about 2·10¹⁷. From that table, the gravitational acceleration of metals is on the order of 10⁻¹⁴ m/sec² as compared to the Earth's overall gravitational acceleration of about 9. 8 m/sec² for a ratio of about 10¹⁵. Consequently, the flux actually carrying the light [generated by a metallic light source] and entering the slit is the dominant factor.

The U-wave fluxes are proportional to the acceleration that they produce. The ratio of the accelerations, which is the ratio of the U-wave fluxes, is as given in equation 4-1, below.

$$\begin{matrix}Ratio = \frac{Acceleration of Earth Gravity}{Acceleration of Diffracted Light U \text{-} waves} \\ = \frac{Earth Gravity U \text{-} waves Flux}{Slit Diffracted Light U \text{-} waves Flux} \\ \approx {10}^{15}\end{matrix} \qquad ( 4 \text{-} 1 )$$

Therefore the U-wave concentration which all vertical rays of gravitational U-wave flux must be forced to encounter by being forced to pass close to the cubic crystal's atoms must for this purpose be made 10¹⁵ times greater. The gravitational U-wave flux must be forced to pass accordingly even closer to the cubic crystal's atoms.

However, the U-wave concentration from the atoms is inverse-square reduced with distance from the atom and accordingly so increases with nearness to the atom. Consequently, to increase the concentration by a factor of 10¹⁵ requires reducing the separation distance by a factor of only the square root of that, about 3.2·10⁷.

The earlier above found effective interatomic spacing to be forced by tilting the cubic crystal, 2×[4.9·10⁻¹²]=9.8·10⁻¹² meter, must now be that divided by 3.2·10⁷ the result for which is 3·10⁻¹⁹ meter. That arrangement, arranging that all of the U-wave gravitational flux must, at some layer, pass within 3·10⁻¹⁹ meter of an atom of the cubic crystal will result in essentially 100% of the gravitational U-wave flux passing so close to some atom that it should be deflected by 45° or more.

Treating that case, such results can be accomplished by tilting the crystal slightly away from the vertical so that the atoms of the lattice are not directly above each other. The Earth's gravitational field is radially outward from the center of the Earth. At any modest sized location area on the Earth's surface the rays of that field's U-wave flow are purely vertical.

With the cubic crystal's natural interatomic spacing being 2.7·10⁻¹⁰ meter and the effective spacing to be forced is 3.10⁻¹⁹ meter then each natural interatomic space must be sub-divided into 9·10⁸ “pieces”. If the crystal is tilted such that each of the layers of the crystal lattice is located offset from the layer below it by [ 1/9·10⁸]·[2.7·10⁻¹⁰]=3·10⁻¹⁹ meter in each of the two horizontal directions of the orientation of the lattice then the objective is met.

The direct implementation of that would require a tilt at an angle whose tangent is the offset divided by the interatomic [layer-to-layer] spacing, [3·10⁻¹⁹]÷[5.4·10⁻¹⁰]=5.6·10⁻¹⁰, an angle of about 6.4·10⁻⁸°. That means that the tilt causes each successive layer to offer its atoms a further 3·10⁻¹⁹ meter offset so that enough layers will produce offering the atoms at every 3·10⁻¹⁹ meter increment in each 2.7·10⁻¹⁰ meter horizontal interatomic space. See Drawing 4-2.

The required number of layers is one layer for each of the 9·10⁸ “pieces” into which each 2.7·10⁻¹⁰ meter horizontal interatomic space is divided: 9·10⁸ layers.

Such a fine tilt angle and its precision are unlikely if not impossible to set up. The solution to that is that the successive layers need not each supply the minute offset relative to their adjacent layers. If the layers as depicted in Drawing 4-2 were shuffled into any order whatsoever, they would still have the same effect that no vertical ray could avoid passing within 3·10⁻¹⁹ meter of an atom, some atom, not necessarily one in the immediately next layer.

Of course, the layers in the cubic crystal cannot be shuffled or re-arranged, but that is not necessary. All that is necessary to operate using a larger tilt angle is that the same sufficient number of layers overall be employed and that the tilt be such [“workable tilt”] that the actual x-axis offset and the actual y-axis offset be such that, after that “same sufficient number of layers overall”, each required effective atomic position appears somewhere, in some layer, even though not necessarily in “sequential order”.

“Unworkable tilts” are those that duplicate needed atomic positions or that fail to produce all needed atomic positions, or both. The problem of what successfully workable tilts are and how they relate to unworkable tilts is developed in Appendix B, Cubic Crystal Tilt Requirements and Calculations.

The number of layers required, 9·10⁸, requires a cubic crystal thickness of that number of layers multiplied by the individual layer thickness, which is 9·10⁸×5.4·10⁻¹⁰=0.49 meters or 49 cm.

Each “slit” in the cubic crystal is a pair of atoms spaced apart horizontally by the crystal lattice interatomic spacing of 2.7·10⁻¹⁰ meter; or, more precisely, each “slit” is a linear “string” of such atom pairs, in any single layer of the crystal, and running from one side to the other of the crystal just as the slit edges in the case of light diffraction by a slit is a linear “string” of the atoms of which the slit edge consists.

For each such 2.7·10⁻¹⁰ meter wide “slit” the above tilt procedure implements arranging that out of all of that portion of the total gravitational U-wave flux that passes through it, the 1/9·10⁸ or 1.1·10⁻⁷% on either side, a total of 2.2·10⁻⁷% , passes within 3·10⁻¹⁹ meter of an atom of the cubic crystal lattice and will be deflected by 45° or more away from its pre-deflection vertically upward direction. That leaves the issue of what happens to the balance of the gravitational U-wave flux entering each such “slit”.

[The earlier above calculation that 1.8% on each side, a total of 3.6%, would be so deflected was for the case of deflection by the individual atoms of the slit material of the U-wave flux of the light source in the case of light diffraction at a slit. Deflection of the much stronger Earth gravitational U-wave flux by the U-wave flux of individual atoms is much less as already described.]

The U-wave propagation of each such atom falls off in concentration inversely as the square of the distance from it. The 31]10⁻¹⁹ meter closeness is required to obtain the 45° deflection. Of the total gravitational U-wave flux entering that slit, at ten times farther away from an atom, 3·10⁻¹⁸ meter, the concentration is reduced by a factor of [ 1/10]²= 1/100. There the angle of deflection is reduced by approximately that factor to about 0.45°. That deflection is experienced by about 1.1·10⁻⁶% on either side out of the total gravitational U-wave flux that passes through the “slit”, a total of 2.2·10⁻⁶%.

Still farther away, at 3·10⁻¹⁷ meter from an atom, the concentration is reduced by a factor of [ 1/100]²= 1/10,000. There the angle of deflection is reduced by approximately that factor to about 0.0045° and applies to about 2.2·10⁻⁵%.

Thus far more than 99% of the total U-wave flux entering the “slit” experiences negligible deflection. That is, until layer-by-layer in the crystal lattice further portions having earlier experienced that negligible deflection then experience the “3·10⁻¹⁹ meter” condition until, eventually, all of the U-wave flux experiences the “3·10⁻¹⁹ meter” condition and is deflected by 45° or more.

Returning to the mean free path analysis at equations (2-5)-(2-7) it is now found to be the case that the target interatomic spacing to be achieved by the tilt of the cubic crystal is 3·10⁻¹⁹ meters instead of 10⁻¹⁸ meters. The mean free path in the Earth for that same 3·10⁻¹⁹ meters target size then is calculated as follows.

$$\begin{matrix}MFP = 1 / C \cdot A \\ = \frac{1}{\begin{matrix}[ C , Atoms Per Unit Volume ] \cdot \\ [ A , Atom Cross Section Area ]\end{matrix}}\end{matrix} \qquad ( 4 \text{-} 2 )$$

For the Earth the concentration of atoms is on the order of C=5·10²⁸ per cubic meter. In the cubic crystal deflector the target spacing achieved by the tilt is 3·10⁻¹⁹ meters. Each target has cross sectional area space available to it equal to a circle of that diameter so that

A=π/4·[3·10⁻¹⁹]²=7.1·10⁻³⁸ meter² (4-3)

and, for such targets the mean free path per equation (B-9) in the Earth's outer layers is

MFP=2.8·10⁸ meters. (4-4)

That is to be compared to the mean free path in the cubic crystal deflector being one-half the cubic crystal thickness of 0.49 meters or 0.25 meters.

Section 5—Conceptual Applications of Gravitic Deflector Arrays

### Objectives of Gravitics Applications

The objective of gravities is to modify the gravitational effect by controlling the U-wave flow that produces gravitation. The modifications to gravitation-causing U-wave flow that would appear to be potential objectives would include the following.
Diverting the direction of flow of the gravitational field (the U-wave flow from the gravitating mass, e.g. the Earth) so that it does not act on an object body (e.g. an “air car”) and that body consequently becomes free of gravitational attraction or experiences reduced gravitational attraction toward the gravitating mass (the Earth).
   Depending on how effective were the diverting of the natural gravity away from the object body, this would have the effect of levitating or “floating” the body.
   Full cancellation of natural gravitational action on the body would result in its accelerating upward under the effect of centrifugal force due to the Earth's rotation. That acceleration varies according to the latitude of the location on the Earth from on the order of 3/1000 of gravity to zero at the poles.
   Collecting additional flow of the gravitational field, flow that would otherwise miss encountering the object body, and re-directing it onto the object body so that the body becomes attracted by a new or additional gravitational force. That force might be directed:
      In the same direction as that of the natural gravitation (i.e. “down”).
      In a direction different (e.g. “up” or “forward”) from that of the natural gravitation.
      Such effects could be used to control levitation or to provide lateral acceleration. In space one could cancel the gravitational attraction from the rear and enhance it from the forward direction, “rear” and “forward” pertaining to the start and destination of travel.

As so far developed, the science of gravities is only able to produce deflection of some significant portion of the natural upward-flowing/downward-attracting gravitational U-wave flow away from the vertical so that it is possible to generate reduced, possibly zero, gravitation in the region above such a deflector.

Gravitic Levitation and Acceleration

Drawing 5-1 shows an arrangement deflecting gravitational field away from an object body, levitating it. [It also has the incidental effect of somewhat attracting objects surrounding the levitated object and subjecting those surrounding objects to added gravitation downward.]

Energy

But such phenomena raise the interesting question, “Where does the energy come from?” In levitating an object, that is in causing it to simply float without motion, the problem of energy is not as obvious as with horizontal acceleration. When an object is accelerated its kinetic energy increases. That energy increase must come from some source. But, what is that source?

The energy comes from the flowing U-waves. When a mass is at an elevated location in a gravitational field we say that the mass has potential energy due to that location in the field. If whatever restraint keeping the mass elevated (for example a shelf on which it resides) is removed the mass falls. It accelerates downward in the gravitational field. Its potential energy is converted into kinetic energy.

However, speaking about that as if it is the mass that has the potential energy is not correct. It is the field that has the potential energy. Consider two masses identical except that one, Mass A, has a strong negative charge and the other, Mass B, is charge neutral. Let them both be located the same distance from a strongly positively charged object. In that situation Mass A has potential energy due to the electrostatic field. But Mass B has no such potential energy. The masses being identical the energy must reside in the field, not the bodies.

Furthermore, electrostatic field and gravitational field are not “static”. They both are due to the continuous flow of medium outward from its source, which is the cores of the particles that make up the atoms of matter. The particular “piece” of medium, that is the particular cycle of its oscillation, that encounters a mass at any moment then flows onward. The overall effect of the medium flow on the encountered mass is the successive effect of the successive different “pieces” of the medium flowing and encountering the mass. Each “piece” carries potential energy. The source of all of that potential energy is the original supply of medium in the cores (now somewhat depleted by the on-going outward flow of medium from the cores).

The acceleration and increase in kinetic energy obtained by diverting the gravitational field is “free”, just as “free” as the acceleration and increase in kinetic energy obtained by falling off a cliff. However, in the case of deflected gravitation the “fall” can be indefinitely continuous; it is not required to climb back up to the top of the “cliff” to get more “free” falling down.

Gravitic Power Generation

Not only could “free” acceleration be obtained by appropriately manipulating the gravitational field, “free” power generation should be able to be so obtained. Some of the energy in the flowing U-wave stream can be extracted and converted to heat energy or electrical energy or whatever form is desired.

As Drawing 5-1, above, illustrates, a gravity free region is created above the deflector. That means that the air above the deflector has no weight. The result is that the air above the array rises and air from the sides is drawn in. That air drawn in also becomes weightless and rises and the process continues.

Drawing 5-2 depicts a gravitic electric generator based on that principle but using water rather than air.

The device is very similar to an ordinary hydroelectric generator, which operates by using the potential energy of water at an elevation (called the head) converted to kinetic energy of the water's flow. The flow spins a water turbine which is on the same drive shaft (perhaps via a gear box) as an electric generator.

That type of arrangement and action can operate in air, or water, or any other working fluid. The circulating flow can power a wind turbine or a water turbine and the turbine can drive an electric generator. The overall effect is the extraction of electrical power from the gravitational field exactly equivalently to the action of a hydro-electric station except that the gravity-deflecting form of electrical station can be located wherever one wishes and requires no suitable river and massive dam.

The dimension “head” in Drawing 5-2 is the head, the distance that the center of gravity of the fluid before falling is above its center of gravity after falling, and may be made to be of whatever reasonable size desired. Of course, there is a need to control the process. While that could be done by varying the gravitic action it might be easier to control the process by means of a valve that can vary the water flow continuously over the range from full flow to no flow.

A second form of gravito-electric power plant obtains the generation of rotary motion to drive the electric generator by using a flywheel. A massive wheel is schematically divided into two halves side by side horizontally. A gravitic deflector is placed into operation underneath one of the halves.

The result is that the part of the wheel above the deflector weighs less than its other half. The lighter half rises while the heavier descends producing a continuous rotation. That rotation drives the turbine that drives the electric generator.

A detailed design analysis of gravito-electric generating systems is at Appendix C, “Gravito-electric Generator Design and Calculations”.

Gravitic Powered Vehicles

In principle, it is possible to develop designs of gravitic powered ocean vessels. Other design developments might lead to gravitic powered, air and land-based transportation systems.

Gravity Management Means for These Applications

The principle gravity management means developed in the preceding analysis is the Cubic Crystal Deflector which, by scattering gravitation-causing U-waves away from their natural upward direction, reduces their natural gravitational action on whatever mass is located above it.
Any non-negligible reduction of natural gravitation should be sufficient to drive gravitic power generators so a Cubic Crystal Deflector, if practical at all, should be directly and successfully applicable for that purpose.
For the objective of vehicle levitation such a device would only be successful if it could reduce natural gravitation to, or below, the amount of the Earth's rotation-caused centrifugal acceleration at the vehicle's latitude.
For re-directing natural gravitation so as to act horizontally to accelerate a levitated vehicle some other gravitation management device would be needed.

Research and development are needed to achieve better gravitation control and to make possible levitation and upward acceleration that do not depend on the Earth's rotation. They are also needed to make possible directed control of horizontal acceleration. Such control would also be needed to provide “artificial gravity” in space travel applications.

### General Design Considerations Affecting Gravitic Applications

Force and Acceleration

Gravitation operates differently from all of the other actions, with which we are familiar. In the case of those other actions it is force which is applied. The result is acceleration according to Newton's 2nd Law of Motion per equation (5-1), below.

$$Acceleration = \frac{Force}{Mass} \qquad ( 5 \text{-1} )$$

That is: The force is the input and the result is an acceleration the amount of which decreases as the mass to which the force is applied is greater.

In the case of gravitation it is an acceleration which is imposed by the gravitational action. The gravitational action delivers whatever amount of force it takes to produce that acceleration. Per Newton's 2nd Law of Motion, that amount of force, required and delivered by the gravitational action to produce the acceleration that it produces, is as given in equation (5-2) below.

Force=Mass×Acceleration (5-2)

That is: The acceleration is the input and the gravitational action delivers force in the amount needed to produce that acceleration, which amount of force increases as the mass which it accelerates is greater.

In non-gravitational actions different forces may act on different parts of an overall assembly and the combined effect must be evaluated. One examines the forces that are acting to determine what the net force is and then determines the acceleration by dividing that net force by the overall mass.

Our natural experience does not include situations in which different gravitational actions are applied to different parts of an assembled object. Rather, in our natural experience, gravity is on the largest scale that we experience and everything that we encounter is affected by the same amount of gravity, the same gravitational acceleration.

But, gravitic actions involve manipulating gravity so that some parts of an object experience different gravitation than the other parts. The procedure for determining the overall net effect requires the following steps.
Step 1. For each part of the object to which some particular gravitational acceleration is applied calculate the force resulting from equation (5-2).
Step 2. With the force acting on each part so determined then evaluate the net overall force acting on the object.
Step 3. Then calculate the net overall acceleration of the object from equation (5-1).

Passengers and Cargo in Gravitic Transportation Vehicles

Another way in which dealing with gravitation is different from the situations that one is used to encountering is with a gravitationally levitated flying vehicle.

Fundamentally such a machine would consist of a passenger or cargo cabin with supporting structure and with devices arranged so that the overall net gravitational effect is cancelled or is partially reversed to give a desired acceleration upward. On the other hand, the human passengers and some kinds of cargo would react poorly to experiencing gravity acting in other than the normal surface-of-the-Earth manner.

Therefore the design should leave natural gravitation operating on the sensitive cargo/passenger cabin and apply sufficient managed gravitation to the rest of the vehicle so that the desired overall net vehicle levitation can be obtained while the passengers and sensitive cargo experience no different gravitation than at the Earth's surface except during initial ascent to an operating altitude.

That solution could be taken a step further. In a vehicle accelerating upward at 0.3×g (g=Earth surface normal gravitation, about 9.8 meter/sec²) in the Earth's normal gravitational field the passengers experience the sum of the vehicle acceleration and the natural gravitational acceleration, a total acceleration of 1.3×g. That makes the passengers feel as if they are 30% heavier than normal. If during that ascent the natural gravitation in the passenger cabin were reduced to 0.7×g, then the ascending passengers would feel only a net acceleration equivalent to natural gravity, that is about [0.7×g]+[0.3×g]=g.

### Conclusion

The most likely achievable gravitic effect at the present would be using a properly tilted cubic crystal to produce scattering of the gravitational U-wave flux sufficient to detectably and perhaps usefully reduce the natural gravitational attraction on an object above the cubic crystal.

Demonstration of detectable such scattering would be a major confirmation of the entire U-wave and gravitation theory of The Origin and Its Meaning.

Following demonstration of such effective scattering the next objective would be to demonstrate the extraction of energy from the gravitational field as presented with regard to the proposed gravito-electric generator.

Success with gravito-electric energy generation would lead to numerous beneficial results:
The end of the use of almost all fossil fuel methods of energy generation and their replacement with gravito-electric systems;
The solving of the greenhouse effect cause of planetary climate change;
Energy becoming much less expensive because of zero fuel cost;
Such low cost energy making major ocean water desalination systems practical ending the planetary problems of limited fresh water supplies;
Removal of the dangers of nuclear fission and nuclear fusion energy production; and to some potential problems:
Would the region above a gravito-electric power plant be dangerous for birds?
For airplanes?
For orbiting satellites?
   and even to some novelty:
An entertainment cylinder in which gravity is so reduced that humans could fly if equipped with appropriate wings.
   Of course, the transition to gravito-electric energy would involve major economic and social changes with the associated political conflicts and problems.

Achievement of the foregoing successes would call for major research and development to improve the methods and technology of gravitics. These would hopefully result in gravitic levitation and acceleration/deceleration of transportation devices for both people and freight. They might also be able to produce gravitic systems for interplanetary and intragalactic space travel. Gravitic systems might be able to provide shields for spacecraft by deflecting hazardous particles and objects.

Probably a major objective of such research would be to develop methods of controlled slowing of U-wave propagation so that the direction changing effects of ninety degree right prisms as depicted in Drawing 1-4 and treated in equation (2-2) could be employed.

Appendix A—Relative U-Wave Concentrations: Earth Surface Objects vs. Earth Gravitational Field

For gravitics purposes the interest is in the potential for slowing of the gravitational U-wave flux flowing radially outward from the Earth by some configuration of matter at the Earth's surface. The amount of slowing depends on the relative amounts or concentrations of the opposed-direction U-wave streams per equation (2-1) and its related discussion.

The problem is, then, to determine within a specified type of matter at the Earth's surface the magnitude, u₂, of the component of its ambient U-wave flow that is directly opposite to u₁, the gravitational U-wave propagation arriving from below. Then the slowing of u₁ by u₂ can be determined.

The Ambient U-Wave Flow

The ambient U-wave flow within any type of matter is spherically outward from its source centers-of-oscillation, the atomic components of the matter. Any such stage of this spherical propagation pattern can be split into two hemispheres. That splitting can be chosen to be such that one hemisphere directly faces the rays of incoming U-waves from some external source. Then, the radially outward rays of that hemisphere all have a component, u₂, in the direction directly opposite to the incoming rays of U-waves from the external source, u₁. That situation is depicted in Drawing A-1.

The incoming rays of U-waves from the external source, u₁, are the net sum of rays from many individual centers-of-oscillation, all at a great distance from the source of u₂ and such that they are all effectively parallel and of equal amplitude.

Of course, the rays are not discrete rays neatly arranged along a vertical and a horizontal axis. Rather those shown represent the continuum of medium flow. All of the rays of the components of u₂ opposing u₁ would completely fill the hemisphere volume. The average component magnitude corresponds to that hemi-volume divided by the area of the circular base of the hemisphere.

$$r is the radius of the hemisphere , which here \\ corresponds to the medium amplitude , u ( d ) , \\ where d = r , for a purely radial ray . \\ Volume of Hemisphere = \frac{1}{2} \cdot \frac{4}{3} \cdot π \cdot {r}^{3} \\ Area of Hemisphere Base = π \cdot {r}^{2} \\ Average {u}_{2} = \frac{2}{3} \cdot r and corresponds to \frac{2}{3} \cdot [ u ( d = r ) ] \qquad ( A \text{-} 1 )$$

Some example successive stages of the spherically outward U-wave flow from a single center-of-oscillation are depicted in Drawing A-2.

A single stage, such as that of Drawing A-1, of the smoothly continuous sequence of stages of which Drawing A-2 is a few intermittent examples, is not a solid hemisphere of medium. Rather it is the wave front of medium propagation at an instant of time. A single stage is the outer surface shell of the hemisphere.

The components of medium flow pertaining to that shell act at the curved shell surface, not the theoretical flat circular base of the hemisphere of medium flow. Mathematically one can let the smoothly continuous sequence of such shells be represented by a finite number of nested shells of minute but finite thickness. One such shell is depicted in Drawing A-3.

The inverse-square variation of the medium flow, u (d), with distance, d, from the center of the source particle from which it is propagated is depicted in Drawing A-4.

This amplitude is actually the concentration, the amount of medium per unit area at the surface of a sphere centered on the center-of-oscillation, as depicted in any single stage of the type depicted in Drawing A-2. That amount of medium, itself, is actually the amplitude of the [1−Cos] form of medium oscillation. [The δ in Drawing A-4, above, is the radius of the center-of-oscillation's core.]

Each atom effectively resides in a cube of side s. The center-of-oscillation of the atom is at the center of the cube and propagates U-wave flow outward in all directions. Per the above Drawing A-4, that propagation extends out infinitely in all directions becoming rapidly reduced in magnitude. The cubic volume associated with some single atom experiences the flow of medium from other adjacent and distant atoms through it in addition to its own propagating medium.

Rather than attempt to sum the myriad varied contributions of all of the other affecting sources in the material to the medium flow within a particular atom's volume-cube, the same net effect can be obtained by attributing all the action of that particular atom (and each individual atom) as taking place within its own volume-cube. That is, the effect and action per Drawing A-4 from d=δ to ∞ is attributed all to the volume-cube of its source atom with that volume-cube unaffected by medium from other atoms.

Assuming a uniform composition of the matter in question, the matter within which the ambient U-wave concentration is to be determined, then the average inter-atomic spacing is the same value as the side of the atom's volume-cube, s. That quantity is the cube root of the reciprocal of the density of the matter times the weight of a single component atom.

The maximum hemisphere centered on the center of the atom, the center of the atom's volume-cube, as in Drawing A-2, that can fit within the cube of volume allotted to the atom is of radius R=½S.

The calculation of S is as follows.

$$\begin{matrix}Density = \frac{Weight}{Volume} \\ = \frac{Atomic Weight}{{S}^{3}}\end{matrix} \\ \begin{matrix}{S}^{3} = \frac{1}{Density} \cdot Atomic Weight \\ = \frac{Total Volume}{Total Weight} \cdot [ \begin{matrix}Weight of One Atom = \\ Atomic Mass Number \times \\ 1.661 \cdot {10}^{- 27} kg \text{/} amu\end{matrix} ] \\ = Volume for One Atom\end{matrix} \\ S = {[ Volume for One Atom ]}^{1 / 3} \qquad ( A \text{-} 2 )$$

Table A-5, below, gives some typical values for these quantities using MKSR units (meter-kilogram-second, rationalized units, also now referred to as SI or Standard International units).

From the table it is clear that inter-atomic spacings, S, in solid elements are on the order of 2.0 to 3.0×10⁻¹⁰ meters. In a gas at atmospheric pressure the spacing is on the order of 10⁻⁹ meters. [The value of δ, the radius of the core of a proton or an electron, is 4.05084×10⁻³⁵ meters, on the order of 10⁻²⁵ times smaller].

TABLE A-5
Some Example Inter-Atomic Spacings

| Matter | Density | Weight of Atom | Spacing, S |
|---|---|---|---|
| Air | 16 | 25.9 × 10⁻²⁷ | 1.17 × 10⁻⁹ |
| Water | 1000 | 18. × 10⁻²⁷ | 2.62 × 10⁻¹⁰ |
| Carbon | 2250 | 19.95 × 10⁻²⁷ | 2.07 × 10⁻¹⁰ |
| Aluminum | 2700 | 44.80 × 10⁻²⁷ | 2.55 × 10⁻¹⁰ |
| Iron | 7870 | 92.88 × 10⁻²⁷ | 2.28 × 10⁻¹⁰ |
| Lead | 11342 | 345.35 × 10⁻²⁷ | 3.12 × 10⁻¹⁰ |

The latest medium flow from the source of u₁, that flow which has not yet propagated outward and inverse square diffused, has the greatest concentration of medium per area, but it intercepts only the smallest target area of incoming rays, u₁, because it is the smallest shell, analogous to t1 of Drawing A-2. This is the ray of case “a” in Drawing A-6.

Medium that had been propagated a moment earlier has progressed somewhat in its inverse square diffusion as in case “b” in Drawing A-6. Its concentration of medium per area is less because of the distance that it has propagated, but it intercepts a greater target area of incoming rays of u₁ for the same reason. The situation is similar but more progressed with the further successive cases in the Drawing.

An incoming ray of u₁ that is directed at the center of the encountered center-of-oscillation will encounter all of the cases depicted in Drawing A-6, as indicated in the Drawing. But an incoming ray that is directed at a point some lateral distance away from the center of the encountered center will encounter only those cases of Drawing A-6 which overlay its path. For example: in the Drawing ray #1 intercepts all of cases a, b, c, d and e; however, ray #2 intercepts only cases c, d and e.

All of the cases from “a” through “e” and beyond, that is all of the shells from d=δ to d=∞ can be summed as infinitesimally thick individual shells by the process of integration as follows.

An intermediate ray, such as ray #2 in the above Drawing, intercepts all of the cases/shells with a greater radius than the intermediate ray's lateral displacement from the center of the center. If we let r represent that lateral displacement of the ray, d the distance outward from the source of u₁ that the shell has traveled, and U_{c} the fundamental amplitude per equations (1-1) and (1-2), then the summation of the concentrations that that ray encounters in the various shells on outward from lateral displacement r is as follows (the ⅔ is to deal in average per equation (A-1)).

$$\frac{2}{3} \cdot {\int }_{r}^{∞} \frac{{U}_{c}}{4 \cdot {d}^{2}} d d \qquad ( A \text{-} 3 )$$

This equation (A-3) is the product of medium flow concentration and a distance (the variable of integration, d). That which is needed is the average medium flow concentration within the atom's volume cube, that is over the range d=∞ to R (R=½·s=[the volume cube side]). The integration on the variable d to ∞ then divided by the distance only out to R attributes all of the atom's medium flow propagation solely to its own volume-cube.

Therefore, dividing equation (A-3) by [R−δ]=R because R>>δ and performing the integration the equation (A-4), below, is obtained.

$$\begin{matrix}\frac{2}{3 \cdot R} \cdot {\int }_{r}^{∞} \frac{{U}_{c}}{4 \cdot {d}^{2}} d d = \frac{{U}_{c}}{6 π \cdot R} \cdot {⌈ - \frac{1}{d} ⌉}_{r}^{∞} \\ = \frac{{U}_{c}}{6 π \cdot R \cdot r}\end{matrix} \qquad ( A \text{-} 4 )$$

In Drawing A-6, while ray #1 encounters the greatest concentration of medium flow, only a very minor portion of the total incoming rays of u₁ can be in position to experience that concentration. On the other hand, ray #2, encounters a reduced medium flow concentration but a much larger number of rays can have that experience. The number of rays that can experience the medium flow concentration for any particular lateral displacement, r, is the area of the concentric ring of radius r and thickness dr. For each of the r's of equation (A-4) the number of incoming rays of u₁ that encounter that concentration is thus 2π·r·dr.

Therefore, equation (A-4), above, must be integrated by the factor 2π·r·dr over the range that r can have within the atom's volume-cube, from r=δ to r=R. That process weights each of the different medium flow concentrations encountered by incoming rays that lie in the successively greater r displacement rings and sums the weighted values. Then dividing that result by the overall target area involved, π·[R²−δ²]=π·R² because R>>δ, gives the average medium flow concentration contributed by actions within the hemisphere of radius R centered on the center of oscillation and oriented toward the incoming medium flow.

$$\begin{matrix}\frac{1}{π \cdot {R}^{2}} \cdot {\int }_{δ}^{R} 2 π \cdot r \cdot [ Equation ( A \text{-} 4 ) ] \cdot d r = \frac{1}{π \cdot {R}^{2}} \cdot {\int }_{δ}^{R} 2 π \cdot r \cdot \\ \frac{{U}_{c}}{6 π \cdot R \cdot r} \cdot d r \\ = \frac{1}{π \cdot {R}^{2}} \cdot \\ {\int }_{δ}^{R} \frac{{U}_{c}}{3 \cdot R} \cdot d r \\ = \frac{{U}_{c}}{3 π \cdot {R}^{3}} \cdot [ R - δ ] \\ = \frac{{U}_{c}}{3 π \cdot {R}^{2}}\end{matrix} \\ [ R - δ = R because R >> δ ] \qquad ( A \text{-} 5 )$$

This average medium flow concentration contains the only medium flow components, u₂, directly opposing the incoming medium flow, u₁, present within the hemisphere within the cube of volume allocated to the atom. That medium concentration must be averaged over the overall cube of atomic volume. The result is the average medium flow concentration throughout the hypothesized piece of matter.

$$\begin{matrix}Overall Average Concentration = \frac{{U}_{c}}{3 π \cdot {R}^{2}} \cdot \\ \frac{Hemisphere Volume}{Atomic Cube Volume} \\ = \frac{{U}_{c}}{3 π \cdot {R}^{2}} \cdot \\ \frac{1 / 2 \cdot [ 4 / 3 \cdot π \cdot {R}^{3} ]}{{S}^{3}} \\ = \frac{2 \cdot {U}_{c} \cdot [ 1 / 2 \cdot S ]}{9 \cdot {S}^{3}} \\ \frac{{U}_{c}}{9 \cdot {S}^{2}}\end{matrix} \\ [ R = 1 / 2 \cdot S ] \qquad ( A \text{-} 6 )$$

However, this calculation has been for a simple center-of-oscillation such as a proton or an electron. In general, atoms in matter consist of a number of such particles in combination. More precisely the nucleus of an atom is effectively the result of the combining of A protons and A-Z electrons into one overall new center-of-oscillation oscillating in a complex manner. A is the atomic mass number and z is the atomic number. [See Section 17, The Atomic Nucleus—The Nuclear Species, in The Origin and Its Meaning¹. [1] R. Ellman, The Origin and Its Meaning, The-Origin Foundation, Inc., http://www.The-Origin.org, 1997. [The book may be downloaded in .pdf files from http://ww v.The-Origin.org/download.htm].

The oscillation amplitude is the same for all the various nuclear specie and is not of interest here in that gravitation is an average effect. The average value of the complex oscillation of an atomic nucleus is equal to Z·U_{c}. The oscillation [in matter as compared to anti-matter] is entirely within the +U region of medium (with the sole exception of the Hydrogen isotopes, Deuterium and Tritium, which are not of significance here).

That average value is the result, however, of a +U average value of A·U_{c} and a −U average value of [A-Z]·U_{c}. That is, the atomic nucleus propagates an average medium amplitude of A·U_{c} in +U and simultaneously an average medium amplitude of [A-Z]·U_{c} in −U.

Furthermore, the atom's orbital electrons collectively propagate at the same time an average medium amplitude of Z·U_{c} in −U. Those sources of medium flow are not located at the atomic nucleus, but their average effect is as if they were so located because of their orbits around the atomic nucleus.

The total medium flow concentration in a piece of solid matter made up solely of atoms of specie [^{Z}(Element Symbol)_{A}] is, then, A·U_{c} in +U plus [A-Z]+Z=A·U_{c} in −U. That is a collective medium flow concentration of 2·A·U_{c}, Equation (A-6) then becomes as follows for any such matter.

$$Medium Flow Concentration Within Matter = \frac{2 \cdot A \cdot {U}_{c}}{9 \cdot {S}^{2}} \qquad ( A \text{-} 7 )$$

Using this result, the relative medium flow concentrations in various forms of matter can be compared. This is done at Table A-7, below, for the same substances as listed in the preceding Table A-5, using the values of S =[the inter-atomic spacing] from that table.

TABLE A-7
Some Example Medium Flow Concentrations, u₁, In Matter

| Matter | Atomic Wt, A | Spacing, S | Ambient Medium |
|---|---|---|---|
| Air | 14.99 amu | 1.17 × 10⁻⁹ | U_{c} · 2.43 × 10¹⁸ |
| Water | 18.02 amu | 2.62 × 10⁻¹⁰ | U_{c} · 5.83 × 10¹⁹ |
| Carbon | 12.01 amu | 2.07 × 10⁻¹⁰ | U_{c} · 6.23 × 10¹⁹ |
| Aluminum | 26.98 amu | 2.55 × 10⁻¹⁰ | U_{c} · 9.22 × 10¹⁹ |
| Iron | 55.85 amu | 2.28 × 10⁻¹⁰ | U_{c} · 2.39 × 10²⁰ |
| Lead | 207.19 amu | 3.12 × 10⁻¹⁰ | U_{c} · 4.73 × 10²⁰ |

The Incoming Gravitational U-Wave Flow

Equation (A-7) gives the value of u₂, the ambient U-wave flow within matter, which ambient flow slows the incoming gravitational flow, u₁, per equation (2-1. Having determined the value of u₂ it is now necessary to do that for u₁.

The gravitational U-wave front, u₁, is horizontal, that is all rays are vertical, per Huygens Principle applied to the myriad individual wavelets of the myriad gravitating atoms of which the Earth is composed.

The gravitational acceleration produced by one proton acting on a second proton at a separation distance of one meter is as follows.

$$\begin{matrix}{a}_{g} = G \cdot \frac{{m}_{p}}{{d}^{2}} \\ = ( 6.67 \cdot {10}^{- 11} ) \cdot \frac{1.67 \cdot {10}^{- 27}}{12} \\ = 1.12 \cdot {10}^{- 37} meter \text{/} {second}^{2}\end{matrix} \qquad ( A \text{-} 8 )$$

The medium flow concentration producing that acceleration is as follows.

$$\begin{matrix}{u}_{g} = \frac{{U}_{c}}{4 π \cdot {1}^{2}} \\ = {U}_{c} \cdot [ 7.96 \cdot {10}^{- 2} ]\end{matrix} \qquad ( A \text{-} 9 )$$

The ratio of these, that is the gravitational acceleration per amount of medium flow concentration is:

$$\begin{matrix}\frac{{a}_{g}}{{u}_{g}} = \frac{1.12 \cdot {10}^{- 37}}{{U}_{c} \cdot [ 7.96 \cdot {10}^{- 2} ]} \\ = \frac{1.41 \cdot {10}^{- 36}}{{U}_{c}} relative meter \text{/} {seconds}^{2}\end{matrix} \qquad ( A \text{-} 10 )$$

However, this result is only the case when the source of the gravitational field is a proton having a proton's mass, and, therefore, a proton's U-wave oscillation frequency. The gravitational effect is directly proportional to the mass of the source of the gravitational field and the frequency of that source's U-waves is directly proportional to its mass.

Therefore, in order to apply in general, equation (A-10) must be multiplied by A, the atomic mass in amu of the particular gravitational source, divided by 1.07 . . . the atomic mass in amu of a proton. See equation (A-11).

$$\begin{matrix}\frac{{a}_{g}}{{u}_{g}} = \frac{[ 1.41 \cdot {10}^{- 36} ] \cdot A}{1.07 \cdot {U}_{c}} \\ = \frac{1.32 \cdot {10}^{- 36} \cdot A}{{U}_{c}} relative meter \text{/} {seconds}^{2}\end{matrix} \qquad ( A \text{-} 11 )$$

The ambient U-wave concentration in any particular direction in the several substances listed in the preceding Table A-7 then corresponds to the following gravitational accelerations.

TABLE A-8
Some Example Ambient Internal
Gravitational Accelerations in Matter

| Matter | Atomic Wt, A | Ambient Medium | Grav Accel'n |
|---|---|---|---|
| Air | 14.99 amu | U_{c} · 2.43 × 10¹⁸ | 4.81 × 10⁻¹⁷ |
| Water | 18.02 amu | U_{c} · 5.83 × 10¹⁹ | 1.39 × 10⁻¹⁵ |
| Carbon | 12.01 amu | U_{c} · 6.23 × 10¹⁹ | 9.88 × 10⁻¹⁶ |
| Aluminum | 26.98 amu | U_{c} · 9.22 × 10¹⁹ | 3.28 × 10⁻¹⁵ |
| Iron | 55.85 amu | U_{c} · 2.39 × 10²⁰ | 1.76 × 10⁻¹⁴ |
| Lead | 207.19 amu | U_{c} · 4.73 × 10²⁰ | 1.29 × 10⁻¹³ |

For comparison, the value of the Earth's gravitational acceleration at the surface of the Earth is 9.8 m/sec². Thus the ambient U-wave concentrations, as measured by their equivalent gravitational accelerations, available to produce slowing of incoming gravitational U-wave flow of the Earth are on the order of 10⁻¹⁵ times too small to have any noticeable effect.

Or, looked at the other way, from equation (A-11) the medium flow concentration corresponding to Earth's gravitational acceleration at the surface is

$$\begin{matrix}{u}_{g} = \frac{{U}_{c} \cdot 9 \cdot 8}{1.32 \cdot {10}^{- 36} \cdot A} \\ = \frac{7.94 \cdot {10}^{36} \cdot {U}_{c}}{A}\end{matrix} \qquad ( A \text{-} 12 )$$

The principal components of the Earth are approximately as given in Table A-9, below. From the table the overall average atomic weight, A, of the Earth is about A=32.5.

TABLE A-9
Earth Average Atomic Weight, A

| Earth | Percent | | Atomic | Contribution to |
|---|---|---|---|---|
| Component | of Total | Symbol | Weight | Average |
| Iron | 31.0 | Fe | 55.9 | 17.3 |
| Oxygen | 30.0 | O | 16.0 | 4.8 |
| Silicon | 16.0 | Si | 28.1 | 4.5 |
| Magnesium | 15.0 | Mg | 24.3 | 3.7 |
| Nickel | 2.0 | Ni | 58.7 | 1.2 |
| Calcium | 1.5 | Ca | 40.1 | 0.6 |
| Aluminum | 1.3 | Al | 27.0 | 0.4 |
| Other | 2.0 | — | — | — |

| | |
|---|---|
| Earth Average Atomic Weight, A | 32.5 |

### Conclusion and Ratios

Therefore, u_{g} at the Earths' surface is on the order of

u_{gravitational}=u₁≈2·10³⁵·U_{c}

compared to the ambient U-wave flow concentrations in matter of on the order of

u_{local ambient}=u₁≈1·10²⁰·U_{c}

per the preceding Table A-8 so that

u_{gravitational}≈10¹⁵·u_{local ambient}

It would thus appear that the medium flow concentration of Earth surface gravity is so immensely greater than the ambient flow in local matter that no useful slowing of the Earth's gravitational flow can be directly effected by a modest amount of matter. Put in other terms, the index of refraction of the Earth's gravitational U-wave flow remains unchanged for practical purposes regardless of the local matter or empty space through which it passes.

For a useful interaction of matter and gravitational field to take place it would be necessary either to have matter with on the order of 10¹⁵ times more ambient U-wave flow or a region in space with on the order of 10¹⁵ times less gravitational U-wave flow or some mixture of those two differences. The former case would require matter of immense density and the latter case gravity so weak that control of it would be of little interest.

Thus the direct use of natural local matter itself to deflect, refract, or otherwise affect or control gravitational U-waves appears to be self-defeating in that the amount of matter needed to produce a useful U-wave medium concentration would itself be an immense gravitating mass. And, thus, practical gravitics requires finding alternative methods of gravitational U-wave management.

That is, unless a way can be found to increase the effective value or the effectiveness of u_{local ambient}.

Appendix B—Cubic Crystal Tilt Requirements and Calculations

If it were possible to set the minute tilt angle so that the minute offset of 3·10⁻¹⁹ meter could be precisely set and maintained, the “fundamental case”, such that the first lattice layer offset is that amount and successive multiples of it sequentially are in the successive layers [2^{nd} layer offset is twice the initial layer; 3^{rd} layer offset is thrice the initial layer; etc.], that direct approach would be taken.

However, the setting of such a minute angle and offset, much less doing so sufficiently precisely, is not practical and probably impossible. To operate using a larger and less precise tilt angle, any tilt angle, the same sufficient number of layers overall required for that “fundamental case” must be employed and the tilt must be such that the actual x-axis offset and the actual y-axis offset are such that, after that “same sufficient number of layers overall”, each required atomic position appears somewhere, in some layer, even though not necessarily in “sequential order”.

### The Exact Submultiple of Interatomic Spacing Issue

The most obvious condition of tilt angle and offset that would interfere with “each required effect appearing somewhere, in some layer” would be the actual offsets being an exact sub-multiple of the actual interatomic spacing.

For example: with a tilt angle tangent of 0.01, a tilt angle of 0.57°, the layer-to-layer offset would be 0.01 of an interatomic spacing. Layer #2 would be offset 0.01×(2.7·10⁻¹⁰)=2.7·10⁻¹² meter from layer #1, layer #3 the same from layer #2 . . . , and layer #101 would be offset a total of 2.7·10⁻¹⁰ meter, the actual interatomic spacing, from layer #1. In that circumstance any further layers would only reproduce the atom locations relative to the vertical U-wave flux that the first 100 layers had introduced.

But if the layer-to-layer offset were such that by layer #101 they accumulated an additional 3·10⁻¹⁹ meter total offset from layer #1, then the second 100 layers would deliver atoms all spaced that 3·10⁻¹⁹ meter beyond the atoms of the corresponding layers of the first 100 and the third 100 layers would be correspondingly offset from the second, and so on to ultimately delivering an atom in each of 3·10⁹ intervals in each 2.7·10⁻¹⁰ meter interatomic space horizontally in the crystal.

If that “additional 3·10¹⁹ meter total offset” were, instead, any integer multiple of that amount [but still much less than the 2.7·10⁻¹⁰ actual interatomic spacing] the same overall result would obtain—the in effect shuffling of the layers of the cubic crystal lattice.

The actual offsets not being an exact sub-multiple of the actual interatomic spacing is essentially automatically assured. The inverse, requiring a perfect integral sub-multiple relationship would be essentially impossible in practice. That is determined as follows.

A rational number is a number that can be expressed as the ratio of two integers. A rational number expressed as a decimal fraction always exhibits a repetition, over and over, of the sequence of digits in its expression, for example: 0.33333 . . . =⅓ or 0.125125125=⅛. Conversion of a repeating decimal fraction to the ratio of two integers is done as follows.

$$[ a ] The fraction ≡ F \\ a , b , c , d , … are digits from the set 0 , 1 , … 9 \\ F = 0. abcd … abcd … abcd … \\ [ b ] Where `` n ″ = number of digits in the repetition \\ {10}^{n} \cdot F = abcd … . abcd … abcd … abcd … \\ Then , using n = 4 as an example \text{:} \\ [ c ] {10}^{4} \cdot F - F = abcd \\ 9999 \cdot F = abcd \\ [ d ] F = abcd / 9999 \qquad ( B \text{-} 1 )$$

Any number exhibiting such a repeating sequence is rational. Any number that does not exhibit such a repeating sequence is not rational, cannot be converted per equation (B-1), above, and is therefore irrational.

Consequently, while the number of rational numbers in any interval is finite, the number of irrational numbers in any interval is infinite.

Consider set N, a set of n integers [n finite]: 1, 2, 3, . . . , n. That set is finite, has a finite number of members, is countable and enumerable. Now consider set R, all rational numbers such that each such number has a member of N as its numerator and a member of N as its denominator. There are n members of N. There are n² members of R. The number of members of N and of R is finite.

Now consider set I, all irrational numbers greater than zero and less than n. The number of members of set I is infinite. Therefore, the random selection of any number in the interval zero to n, has an infinite probability of being irrational and an infinitesimal chance of being rational.

Therefore, for any installed tilt angle and the offset that it produces, the chance that it would be an exact sub-multiple of the actual interatomic spacing is nil.

On the other hand, the chance that some particular achieved tilt angle and offset requires more layers of cubic crystal than the “fundamental case” because of inefficient scheduling of successive positions is a significant consideration.

### Temperature Variation

In addition, a number of variable natural effects are much greater than the precise offset of 3·10⁻¹⁹ meter. The effects of temperature variation in the Silicon cubic crystal and various random vibrations within it would overwhelm such a minute setting.

Most materials tend to expand somewhat with increase in their temperature. The measure of that effect is the Thermal Coefficient of Expansion, α. That coefficient relates to thermal expansion of the material as in equation (B-2).

$$Δ L = α \cdot L \cdot Δ T \\ Δ T = change in temperature in degrees centigrade \\ L = length of a dimension of the material \\ Δ L = change in L due to Δ T \\ α = thermal coefficient \\ For Silicon α = {3.10}^{- 6} per degree Kelvin \\ at 20 ° Centrigrade \qquad ( B \text{-} 2 )$$

For the interatomic spacing of Silicon the effect of temperature change is per equation (B-3), below.

$$\begin{matrix}Δ L = α \cdot L \cdot Δ T \\ = [ {3.10}^{- 6} ] \times [ 2.7 \cdot {10}^{- 10} ] \\ = 8 \cdot {10}^{- 6} meters per degree Kelvin\end{matrix} \qquad ( B \text{-} 3 )$$

That as compared to the offset of 3·10⁻¹⁹ meter to be created by the tilt. The one-degree temperature variation is over 2,600 times the objective offset. Even a 1/1000 degree temperature variation is over double the objective offset. For that reason alone, the setting and maintaining of so precise an objective offset is impractical.

The thermal coefficient of Silicon itself varies with temperature. More precisely it ranges from 2.6 to 3.3[×10⁻⁶] over the temperature range of 20° to 100° C.

### Thermal Vibrations and Black Body Radiation

The Silicon crystal, at more or less room temperature and as most other materials at that energy, continuously radiates heat energy at frequencies in the infrared range. [The wavelength of infrared radiation is in the range of 3·10⁻⁴ to 3·10⁻⁷ meters, its frequency being in the range of 10¹² to 10¹⁵ Hz [cycles per second].] The crystal also simultaneously absorbs the same kind of radiation from other objects. Such radiation of that energy comes from a reduction in some atoms' oscillations and such absorption is to an increase in some atoms' vibrations.

If the crystal's temperature is greater than its surroundings its radiated energy exceeds that absorbed and it cools down toward thermal equilibrium with its surroundings. Conversely, if it is cooler than its surroundings its temperature increases due to its absorbing more energy than it radiates.

The heat energy corresponding to the crystals' temperature exists in the crystal as the vibratory oscillations of its atoms about their neutral [temperature=0° Kelvin] position. In a crystal lattice the atoms are bound to their average positions by the neighboring atoms. The spectrum of lattice vibrations ranges from low frequencies to ones on the order of 10¹³ Hz.

The dependency of atoms' vibrations on its neighbors depends on temperature. At room temperature range most of the thermal energy is in the vibrations of highest frequency. Because of the short corresponding wavelength the motion of neighboring atoms is essentially uncorrelated so that the vibrations can be considered as independently vibrating atoms, each moving about its average position in three dimensions.

[At high temperature they are not independent of each other. At higher temperatures, not applicable to the present analysis the adjacent atoms are more interrelated in their motions and result in oscillatory waves in the crystal lattice.]

The thermal expansion with increase in temperature is due to the increased amount of energy [heat] in the crystal, and the consequent increase in the amplitude of the crystal's vibrations. The above calculated change in length in Silicon per degree centigrade is the change in amplitude of the atom's vibration.

The ΔL per degree K [=degree C.] of 8·10⁻¹⁶ meters per interatomic space of equation (B-2) is about 1 part in 3·10⁵ of the interatomic space. Being the amplitude change that occurs per degree in a range of 100 or more degrees that implies a larger overall amplitude of on the order of 100 or more times that, 8·10⁻¹⁴ meters, or about 0.0003 of the interatomic spacing.

The overall net effect of this is that atomic locations and interatomic spacings are continuously shifting and varying in oscillatory fashion. The amplitude of these shifts is only a small fraction of the interatomic spacing of 2.7·10⁻¹⁰ meters.

On the other hand the amplitude of those shifts is on the order of over 250,000 times the 3·10⁻¹⁹ meter objective distance from an atom that is sought to be achieved That is, the lattice thermal vibrations cause the atoms to oscillate back and forth about their nominal neutral position a distance on the order of over 250, 000 times the 3·10⁻¹⁹ meter objective distance from an atom that it is sought to cause all of the Earth's gravitational field to pass in some layer of the crystal.

That 8·10⁻¹⁴ meters oscillatory atomic location range covers over 250,000 desirable or suitable objective atomic locations each one of which is effectively randomly sampled or occupied along with all of the others.

### The Random Distribution Solution to the Crystal Tilt

The original concept of the cubic crystal deflector sought to so position the crystal by tilting it relative to the cubic structure of the crystal that atoms of the crystal are forced to effectively occur at successive locations equivalent to a very close, dense positioning of the atoms as seen from the point of view of the purely vertically upward direction of the rays of the Earth's gravitational field. Such positioning would insure that all of the gravitational field is forced to pass extremely close to an atom somewhere in the crystal and to accordingly be deflected away from its natural vertically upward path.

However, the atoms of the Silicon cubic crystal lattice are not fixed in location relative to each other but, rather, are continuously oscillating or vibrating about their nominal neutral positions.
The vibrations are of various random amplitudes in a range of amplitudes depending on the temperature-determined energy of the vibrations.
The vibrations are at various random frequencies again in a range of frequencies depending on the temperature.
The motion of the atoms in their vibration spans a range of locations encompassing a large number of atomic positions that would have been sought to be achieved in various different layers somewhere in the crystal under the original concept and plan.
That range of motion of the atoms is a small fraction of the neutral interatomic spacing in the crystal.

The net effect of this behavior of the atoms is that the original concept is unworkable. The natural effects of temperature variation and lattice vibrations are much greater than the precise offset intended of 3·10⁻¹⁹ meter. The effects would overwhelm such a minute setting, which is probably too minute to accurately set in any case.

The alternative is to accept the random vibratory behavior of the atoms and incorporate it into the overall design.

First, the vibrations of each atom are largely independent of the behavior of the other atoms because the amplitude of each atom's vibrations are such a small fraction, 0. 0003, of the interatomic spacing. At any instant of time the totality of the atoms behaving randomly means that, for a sufficient total number of atoms [a sufficiently thick crystal], every sought position of an atom appears somewhere in the crystal. The range of the atom's vibrations can be thought of as a single “super atom” that simultaneously is at all of the 3·10⁻¹⁹ meter intervals in its range.

Second, the issue of the tilt angle and offset that it produces now is that of properly staggering the atomic vibration ranges of the atoms in each layer that same range amount. That is, the tilt objective is now to offset the second layer from the first layer by one atomic vibration range, 0.0003, of the interatomic spacing, 0.0003×2.7·10⁻¹⁰=8·10⁻¹⁴ meters.

With the “unit” atomic vibration range being 8·10⁻¹⁴ meters then the tangent of the tilt angle to schedule that range at an equal offset, 8·10⁻¹⁴ meters, in each successive adjacent layer is as below.

$$\begin{matrix}Tan ( Tilt ) = \frac{Offset}{Vertical Layer Thickness} \\ = \frac{8 \cdot {10}^{- 14}}{5.4 \cdot {10}^{- 10}} \\ = 0.00015 \\ Tilt = 0.008 °\end{matrix} \qquad ( B \text{-} 4 )$$

Drawing B-1 illustrates the effect of equation (B-4).

If, instead, the layer to layer offset is set at eleven times the “unit” atomic vibration range of 8·10⁻¹⁴ meters, that is [11]×[8·10⁻¹⁴] meters in each successive adjacent layer the tilt is per equation (B-5).

$$\begin{matrix}Tan ( Tilt ) = \frac{Offset}{Vertical Layer Thickness} \\ = \frac{[ 11 ] \times [ 8 \cdot {10}^{- 14} ]}{5.4 \cdot {10}^{- 10}} \\ = 0.002 \\ Tilt = 0.1 °\end{matrix} \qquad ( B \text{-} 5 )$$

That tilt is a not unreasonable value to implement. With it every eleventh layer picks up the position of the second, then third, etc. layer of the equation (B-4) case, the layer to layer offset being equal to the atomic vibration range.

Using a suitably thick section of a commercially grown Silicon cubic crystal ingot 30 cm in diameter. the equation (B-5) tilt angle tangent of 0.002 would be achieved with a 0.6 mm thick shim at the edge of the crystal.

Going still farther, if, instead, the layer to layer offset is set at one hundred one times the “unit” atomic vibration range of 8·10⁻¹⁴ meters, that is [101]×[8·10⁻¹⁴] meters in each successive adjacent layer the tilt is per equation (B-6).

$$\begin{matrix}Tan ( Tilt ) = \frac{Offset}{Vertical Layer Thickness} \\ = \frac{[ 101 ] \times [ 8 \cdot {10}^{- 14} ]}{5.4 \cdot {10}^{- 10}} \\ = 0.015 \\ Tilt = 0.86 °\end{matrix} \qquad ( B \text{-} 6 )$$

That almost 1° tilt is a reasonable value to implement. With it every 101st layer picks up the position of the second, then third, etc. layer of the equation (B-4) case, the layer to layer offset there being equal to the atomic vibration range.

Using a suitably thick section of a commercially grown Silicon cubic crystal ingot 30 cm in diameter. the equation (B-6) tilt angle tangent of 0.015 would be achieved with a 4.5 mm thick shim at the edge of the crystal.

### Precision and Errors

If the intended 4.5 mm thick shim were in error by, for example, about ±0. 5 mm then the actual tilt angle tangent would be about 0.013 to 0.017. That corresponds to the multiple of the “unit” atomic vibration. range being about 87.75 or about 114.75. Either value or any others in that range will eventually produce all of the desired configurations given sufficient layers.

Another precision issue is that of the orientation of the cubic crystal. For the tilt angle to be precise, the bottom of the cubic crystal slab must be exactly one simple layer of the crystal, that is perfectly aligned to the cubic lattice. In addition the surface on which the crystal and shim rest must be perfectly horizontal.

Furthermore, two shims are needed, one for the x-offset and one for the y-offset. Each must be located at a point on the edge of the crystal corresponding to the midpoint of the interatomic spacing central to the greatest parallel diameter. They must be located at 90° relative to each other, corresponding to two adjacent horizontal sides of the cubic structure.

There are several factors in the above overall analysis which, while theoretically valid in general, involve estimates. These include the range of every atom's vibration being the same as that of every other atom, the actual atoms' vibrations range taken to be 8·10¹⁴ meters, the uniformity of those ranges and their overall covering all atomic positions required, and that the atomic vibrations are three-dimensional although the analysis has treated only one-dimensional vibrations as in Drawing B-1.

### Design Summary

The principle design parameters for the initial cubic crystal gravitic deflector are as summarized as follows.

Per the calculations of Section 4, a silicon monolithic cubic crystal slab 49 cm thick or more should result in 100% deflection.

Common commercially produced silicon cubic crystal wafers are on the order of 600 micro-meters [0.6 mm] thick and up to 30 cm in diameter. Using commercial wafers of that type with their very small thickness would be impractical.

Therefore a single thick slab is needed such as is commercially produced to form the ingot from which the commercial wafers are sliced.

With regard to the distance from the top of the cubic crystal deflector to the bottom of the object above it, the greater that distance is the more effectively reduced is the gravitational U-wave flux acting on the object because the scattered rays of gravitational U-wave can more effectively disperse as they have more distance to travel to the vicinity of the object.

The deflector consists of:
A support having a verified horizontal upper surface for the cubic crystal deflector;
A Silicon cubic crystal slab:
   30 cm in diameter,
   49 cm or more thick, and
   with the orientation of the cubic structure determined and noted so that the tilt-producing shims can be properly located;
Precision shims 4.5 mm thick for producing the tilt of the cubic crystal slab.

Appendix C—Gravito-Electric Generator Design and Calculations

### Output Power Calculations

In general the power output of a hydro-electric plant is as given in equation (C-1)⁵. [5] http://en.wikipedia.org/wiki/Hydroelectricity

$$P = head \times flow \times efficiency \times factor \\ where \text{:} \\ P = output power in kilowatts \begin{matrix}head = height through which working fluid falls , in \\ meters\end{matrix} \\ flow = working fluid flow rate in {meter}^{3} \text{/} sec \\ efficiency = fractional mechanical \text{/} electrical efficiency \\ \begin{matrix}factor = conversion factor \\ = 9.8 [ for water @ 1000 kg \text{/} {meter}^{3} and natural gravity \\ of 9.81 meter \text{/} {sec}^{2} ] \\ [ see Δ g , below ]\end{matrix} \qquad ( C \text{-} 1 )$$

Calculations and design of a gravito-electric generator plant are the same as for a hydroelectric plant except as follows.

First an additional factor, Δg, must be added to account for the reduction of gravitation achieved by the gravitic deflector being partial, not comprehensive. That is an effective downgrading of the “natural gravity of 9.81 meter/sec²”, above, and applies wherever “natural gravity” is inherent in the process. In the following it is estimated that Δg=0.5.

Second the flow rate is the continuous rotational flow of the fluid, up in the center of the structure and down in the outer parts. That flow is the velocity times the cross-section area of the flow. The acceleration that the water experiences is to the terminal velocity of an object falling from a height equal to the head. That is for the case of a hydro-electric plant where new, essentially static water is continuously accelerated by the head.

In the gravito-electric case the water continuously re-circulates, the already flowing water receiving continuous additional acceleration through the same head. But, the losses of the water flow to friction and turbulence increase as the velocity of the flow increases. In its steady state the water flow is steady at a velocity at which the additional acceleration just makes up for the friction and turbulence losses plus the power delivered to the turbine.

The component of equation (C-1) that needs development is the “flow”, which develops as follows. The hydro-electric plant acceleration of the water is to the terminal velocity of an object falling from a height equal to the effective head per equation (C-2).

$$s = 1 / 2 \cdot g \cdot {t}^{2} [ in general ] \\ where \text{:} \\ s = distance of fall in meters g = acceleration of gravity in meters / {sec}^{2} \\ t = time duration of fall in seconds v = terminal velocity in meters / sec \\ head = 1 / 2 \cdot 9.81 \cdot Δ g \cdot {t}^{2} [ for this hydro \text{-} electric case ] \\ t = {[ 2 / 9.81 \cdot Δ g \cdot head ]}^{1 / 2} \\ \begin{matrix}v = g \cdot Δ g \cdot t \\ = 9.81 \cdot 0.5 \cdot {[ 2 / 9.81 \cdot 0.5 \cdot head ]}^{1 / 2} \\ = 3.1 \times {head}^{1 / 2} meter \text{/} sec\end{matrix} \qquad ( C \text{-} 2 )$$

Alternatively, the same result is obtained considering energy instead of distance and acceleration, as equation (C-3).

$$Potential Energy converts to Kinetic Energy \\ head \cdot [ g \cdot m ] = 1 / 2 \cdot m \cdot {v}^{2} [ in general ] \\ \begin{matrix}v = {[ 2 \cdot head \cdot g \cdot Δ g ]}^{1 / 2} \\ = 3.1 \times {head}^{1 / 2} meter \text{/} sec\end{matrix} \qquad ( C \text{-} 3 )$$

That acceleration applied repetitively to the water gives a final velocity dependent on the flow path structure and on the power delivered to the turbine. Typically, for a “very open” flow path structure, that final, steady state flow velocity could be on the order of two, five or more times the above calculated “terminal velocity”.

The length of the flow path is essentially twice the “head”, the water traveling the “head” once upward and once downward per cycle. The “very open” cross-section area of that flow path is one on the order of the square of half the head. The conservative flow calculation, using the equation (C-3) velocity, is per equation (C-4).

$$Flow path cross \text{-} section = {[ 1 / 2 \cdot head ]}^{2} \\ \begin{matrix}flow = velocity \times cross \text{-} section \\ = [ 3.1 \times {head}^{1 / 2} ] \cdot {[ 1 / 2 \cdot head ]}^{2} \\ = 0.78 \cdot {head}^{2.5} {meter}^{3} \text{/} sec\end{matrix} \qquad ( C \text{-} 4 )$$

The resulting overall power output is per equation (C-5).

$$\begin{matrix}P ≡ gravito \text{-} electric power output \\ = [ head \cdot Δ g ] \times flow \times efficiency \times factor \\ = [ head \cdot 0.5 ] \times [ 0.78 \cdot {head}^{2.5} ] \times efficiency \times factor \\ = 0.27 \cdot {head}^{3.0} \times efficiency \times 9.8 kilowatts\end{matrix} \qquad ( C \text{-} 5 )$$

For a deflector that deflects only half the gravitation [Δg=0.5] as above and for a mechanical/electrical efficiency factor of 0.75, Table C-1, below, gives some sample values of gravito-electric outputs based on the above. As can be seen the output increases dramatically with physical size because of the exponents in equation (C-5).

TABLE C-1
Example Gravito-electric Power Outputs

| Head | Cross-section | Flow | Power | Power |
|---|---|---|---|---|
| meters | meters² | meters³/sec | kilowatts | horsepower |
| 1 | 0.25 | 0.78 | 2.0 | 2.7 |
| 2 | 1.0 | 4.4 | 16. | 21. |
| 5 | 6.3 | 44. | 250. | 330. |
| 10 | 25.0 | 250. | 2,000. | 2,700. |
| 20 | 100.0 | 1400. | 16,000. | 21,000. |

### Design Considerations

Configuration

Referring to Drawing 5-1 the effect of the gravitic deflector is not only to deflect gravitation away from the object above the deflector, but also to direct that deflected gravitation at an angle toward whatever surrounds the object above the deflector. In other words, the “direct effect” is that the object above the deflector is made to weigh less and the “indirect effect” is that its surroundings are made to weigh more.

The most efficient design for a gravito-electric generator is a circular arrangement as viewed from above as depicted in Drawing 5-2. The fluid above the gravitic deflector, which fluid is the upward path of the fluid circulation pattern, being surrounded by the downward return path of the fluid circulation is an arrangement that maximizes use of the above described “direct effect” and “indirect effect” of the gravitic deflector's action.

In addition, that arrangement is the most compact.

The Working Fluid

The power output calculated per equation (C-5) is based on the working fluid being fresh water, which has a density of 1, 000 kg/meter³. Use of a more dense medium would directly proportionally increase the output power.

However, most liquids have density near to that of water. In general the exceptions tend to have problems of potential corrosiveness or poisoning. The most dense liquids are:
Bromine@ 3.12 times the density of water,
Iodine@ 4.93 times the density of water, and
Mercury@ 13.5 times the density of water.

Another method to increase working fluid density would be to add granular high density particles to the fluid, the fluid being selected for the best viscosity compromise between the effect of the viscosity reducing flow velocity and sufficient viscosity to insure continuous sweeping of the added particles along with the fluid. In that regard water is a fairly viscous fluid and at reasonable velocity successfully sweeps particles along with its flow. The use of such particles might result in unacceptable levels of wear and damage to the turbine mechanisms.

It would appear that methods to increase output by increased working fluid density are not, for gravito-electric power stations, as economically viable as accomplishing equivalent output increase through larger sized gravito-electric units or a greater number of them in parallel.

The Gravitic Deflector

Per the calculations of Section 4, a silicon monolithic cubic crystal slab 49 cm thick or more should result in 100% deflection. Common commercially produced silicon cubic crystal wafers are on the order of 600 micro-meters [0.6 mm] thick and up to 30 cm in diameter. Using commercial wafers of that type would be impractical given the actual requirements.

Therefore a single thick slab is needed. Such slabs exist in the process of manufacturing the common commercial cubic crystal wafers in which the thin wafers are sawed from a large single silicon cubic crystal.

With regard to the distance from the top of the cubic crystal deflector to the bottom of the object above it, the greater that distance is the more effectively reduced is the gravitational U-wave flux acting on the object because the scattered rays of gravitational U-wave can more effectively disperse as they have more distance to travel to the vicinity of the object.

Commercially available cubic crystal ingots are round. For useful applications such as gravito-electric generators, round wafers could readily be trimmed to square or hexagonal so as to fit together in arrays over significant areas.

### Gravitic Power Generation Compact Cases

On the other hand, for applications where minimizing the physical size of the gravito-electric generator relative to its output power is essential such as for land, sea, or air transportation vehicles an alternative arrangement is needed. Such an alternative form is depicted in Drawing C-2.

Here the generation of rotary motion to drive the electric generator is done by means of a flywheel. A massive wheel is schematically divided into two halves side by side horizontally. A gravitic deflector is placed into operation underneath one of the halves.

The result is that the part of the wheel above the deflector weighs less than that its other half. The lighter half rises while the heavier descends producing a continuous rotation. That rotation drives the turbine that drives the electric generator.

The output power calculations for this case are the same as for the case using water as the working fluid except that the flywheel's characteristics are substituted for those of water.
The density of the flywheel material would be on the order of ten times that of water. Therefore the “factor” of 9.8 for water becomes 98. for a typical flywheel.
The flow rate is the flywheel mass cross-sectional area times the tangential velocity of its center of mass.

The power equation then becomes as follows for the flywheel.

$$\begin{matrix}P = head \times flow \times efficiency \times factor \\ = head \cdot Δ g \times [ Cross \text{-} Section Area \times Rotation Speed ] … \\ … \times efficiency \times factor\end{matrix} \\ where \text{:} \\ \begin{matrix}head = height through which the flywheel mass \\ falls in meters \\ flow = flywheel mass cross \text{-} section times its \\ {centroid}^{′} s tangential velocity in {meter}^{3} \text{/} sec\end{matrix} \\ efficiency = fractional mechanical \text{/} electrical efficiency \\ \begin{matrix}factor = conversion factor \\ = 98. [ for typical flywheel material and natural \\ gravity of 9.81 meter \text{/} {sec}^{2} ]\end{matrix} \\ Δ g = factor for deflector effectiveness as before \qquad ( C \text{-} 6 )$$

Assuming that the steady state velocity of the flywheel is ten times the “terminal velocity”, Table C-3, below, gives sample flywheel gravito-electric outputs for a deflector that deflects half the gravitation [Δg=0.5] as before above and for a mechanical/electrical efficiency factor of 0.75 as before above.

TABLE C-3
Example Approximate Flywheel Gravito-electric Power Outputs

| | | Tangential | | |
|---|---|---|---|---|
| | Cross- | Rotation Speed | | |
| Head | section | 31 · head^{1/2} | Power | Power |
| meters | meters² | meters/sec | kilowatts | horsepower |
| 1 | 0.5 | 31 | 570 | 750 |
| 1 | 2. | 31 | 2,300 | 3,000 |
| 5 | 10. | 69 | 130,000 | 170,000 |

### BRIEF SUMMARY OF THE INVENTION

The invention consists of:

[1] A “Gravitic Deflector” using arrangements of atoms, that is configurations of atoms in a piece of material and the orientation of the material relative to the gravitational field, such that for at and near one particular direction through that material the atoms are effectively so spaced, that is located, that all gravitational field acting through the material in that particular direction must pass so close to some atom in the material that the path of propagation of that gravitational field is deflected away from things on the side of the material opposite from that side at which the gravitational field first entered the material with the result that any object or objects on that far side of the material experience less gravitational action than they would otherwise have experienced;

[2] A “Gravitic Reflector” using arrangements of atoms, that is configurations of atoms in a piece of material and the orientation of the material relative to the gravitational field, such that the speed of propagation of that gravitational field is so slowed that reflection of that propagation takes place at the boundary that is the far side of the material as in prism reflecting; and

[3] useful applications of those effects.

### BRIEF DESCRIPTION OF THE SEVERAL VIEWS OF THE DRAWING

This The following Drawings pertain to the “Background of the Invention” as presented in paragraphs #0004 through #12.

| | | |
|---|---|---|
| Drawings | SD-1 through SD-5 | [for the “Summary Development”] |
| Numbers: | 1-1 through 1-6 | [for Section 1] |
| | 2-1 through 2-2, 2-4, 2-6 | [for Section 2] |
| | 3-1 through 3-3, 3-5 | [for Section 3] |
| | 4-1 through 4-2 | [for Section 4] |
| | 5-1 through 5-2 | [for Section 5] |
| | A-1 through A-4, A-6 | [for Appendix A] |
| | B-1 | [for Appendix B] |
| | C-2 | [for Appendix C] |

The following Drawings pertain to the “Detailed Description of the Invention” as presented in paragraph # 0015.

Drawing 1

A gravitic deflector: a static object consisting of a monolithic cubic crystal of dimensions as indicated in the Drawing. The functioning of the Drawing 1 gravitic deflector is to partially deflect the normally vertically upward gravitational field away from vertically upward so that the strength of the gravitational field exiting the top of the deflector is less than the otherwise normal gravitation that entered the bottom of the deflector as depicted in Drawing 3.

Drawing 2

The orientation of the crystal lattice of the gravitic deflector relative to the gravitational field.

Drawing 3

Installation placing and effect of the gravitic deflector.

Drawing 4

Multiple cubic crystals arranged to create large gravitic deflectors.

Drawing 5

A gravito-electric power generator using circulating water [or other fluid].

Drawing 6

A gravito-electric power generator using a massive flywheel.

### DETAILED DESCRIPTION OF THE INVENTION

[1] The Gravitic Deflector

The gravitic deflector consists of a thick monolithic cubic crystal of Silicon or other substance that forms cubic crystals. By monolithic is meant that the deflector is one complete continuous crystal, not a collection of sub-crystals with their boundaries or planes between them. The crystal need not be purely of one atomic element but it is essential that it have the simple cubic crystal structure throughout.

The shape, size, and dimensions of the deflector crystal are shown in Drawing 1. The orientation of the crystal lattice of the deflector relative to the gravitational field to be deflected must be as shown in Drawing 2.

The deflector is static; that is, it is placed under the region or object in which reduction of natural gravitation is to be produced as in Drawing 3, properly oriented per Drawing 2, and functions to produce gravitational deflection so long as it remains so placed and oriented.

Deflectors to produce gravitation reduction over large areas consist of multiple individual deflectors as above shaped into rectangular or hexagonal cross-section so that a number of them can fit together without leaving spaces or gaps as illustrated in Drawing 4.

### [1] Useful Applications

[a] Energy

Applications of gravitic devices brings up the question, “Where does the energy come from?” In reducing an object's weight the problem of energy is not as obvious as with acceleration. When an object is accelerated its kinetic energy increases. That energy increase must come from some source.

The energy comes from the flowing U-waves. When a mass is at an elevated location in a gravitational field we say that the mass has potential energy due to that location in the field. If whatever restraint keeping the mass elevated (for example a shelf on which it resides) is removed the mass falls. It accelerates downward in the gravitational field. Its potential energy is converted into kinetic energy.

However, speaking about that as if it is the mass that has the potential energy is not correct. It is the field that has the potential energy. Consider two masses identical except that one, Mass A, has a strong negative charge and the other, Mass B, is charge neutral. Let them both be located the same distance from a strongly positively charged object. In that situation Mass A has potential energy due to the electrostatic field. But Mass B has no such potential energy. The masses being identical the energy must reside in the field, not the bodies.

Furthermore, electrostatic field and gravitational field are not “static”. They both are due to the continuous flow of medium outward from its source, which is the cores of the particles that make up the atoms of matter. The particular “piece” of medium, that is the particular cycle of its oscillation, that encounters a mass at any moment then flows onward. The overall effect of the medium flow on the encountered mass is the successive effect of the successive different “pieces” of the medium flowing and encountering the mass. Each “piece” carries potential energy. The source of all of that potential energy is the original supply of medium in the cores (now somewhat depleted by the on-going outward flow of medium from the cores).

The acceleration and increase in kinetic energy obtained by diverting the gravitational field is “free”, just as “free” as the acceleration and increase in kinetic energy obtained by falling off a cliff. However, in the case of deflected gravitation the “fall” can be indefinitely continuous; it is not required to climb back up to the top of the “cliff” to get more “free” falling down.

[b] Gravitic Power Generation

A gravito-electric power generating plant is depicted in Drawing 5. The plant uses circulating water or other fluid to drive a turbine which drives an electric generator just as a hydroelectric plant uses falling water. Conceptually the water or other fluid is located inside a hollow torus. The water or fluid torus is schematically divided into two halves side by side horizontally. A gravitic deflector is placed into operation underneath one of the halves.

The result is that the water or fluid above the deflector weighs less than that in the other half of the water or fluid not located above a deflector. The lighter water or fluid rises while the heavier descends producing a continuous rotary-like circulation. That circulation drives the turbine that drives the electric generator.

The practical implementation of this, as in Drawing 5, is as if the above conceptual hollow torus were rotated a full circle around the half having the gravitic deflector underneath. That half is then the center of the overall structure which is circular as depicted in the drawing.

Such plants are similar to hydro-electric plants and have the advantages of hydroelectric plants of non-need of fuel and non-pollution of the environment. However, gravito-electric plants can be smaller; their location is not restricted to suitable water elevations, and the plants and their produced energy are much less expensive.

The gravito-electric type of arrangement and action can operate in air, or water, or any other working fluid; however, the more dense the fluid the smaller the physical size can be. Water is optimum for this purpose. The circulating flow powers a turbine and the turbine drives an electric generator. The overall effect is the extraction of electrical power from the gravitational field exactly equivalently to the action of a hydroelectric station except that the gravity-deflecting form of electrical station can be located wherever one wishes and requires no suitable river and massive dam.

The dimension “head” in the drawing is the pressure head and may be made to be of whatever reasonable size desired. Of course, there is a need to control the process. While that could be done by varying the gravitic action it could also be done by means of a valve that can vary the water flow continuously over the range from full flow to no flow.

### [3] Output Power Calculations

In general the power output of a hydro-electric plant is as given in equation (DD-1)⁵. [5] http://en.wikipedia.org/wiki/Hydroelectricity

$$P = head \times flow \times efficiency \times factor \\ where \text{:} \\ P = output power in kilowatts \begin{matrix}head = height through which working fluid falls , in \\ meters\end{matrix} \\ flow = working fluid flow rate in {meter}^{3} \text{/} sec \\ efficiency = fractional mechanical \text{/} electrical efficiency \\ \begin{matrix}factor = conversion factor \\ = 9.8 [ for water @ 1000 kg \text{/} {meter}^{3} and natural gravity \\ of 9.81 meter \text{/} {sec}^{2} ] \\ [ see Δ g , below ]\end{matrix} \qquad ( DD \text{-} 1 )$$

Calculations and design of a gravito-electric generator plant are the same as for a hydroelectric plant except as follows.

First an additional factor, Δg, must be added to account for the reduction of gravitation achieved by the gravitic deflector being partial, not comprehensive. That is an effective downgrading of the “natural gravity of 9.81 meter/sec²”, above, and applies wherever “natural gravity” is inherent in the process. In the following it is estimated that Δg=0.5.

Second the flow rate is the continuous rotational flow of the fluid, up in the center of the structure and down in the outer parts. That flow is the velocity times the cross-section area of the flow. The acceleration that the water experiences is to the terminal velocity of an object falling from a height equal to the head. That is for the case of a hydroelectric plant where new, essentially static water is continuously accelerated by the head.

In the gravito-electric case the water continuously re-circulates, the already flowing water receiving continuous additional acceleration through the same head. But, the losses of the water flow to friction and turbulence increase as the velocity of the flow increases. In its steady state the water flow is steady at a velocity at which the additional acceleration just makes up for the friction and turbulence losses plus the power delivered to the turbine.

The component of equation (DD-1) that needs development is the “flow”, which develops as follows. The hydro-electric plant acceleration of the water is to the terminal velocity of an object falling from a height equal to the effective head per equation (DD-2).

$$s = 1 / 2 \cdot g \cdot {t}^{2} [ in general ] \\ where \text{:} \\ s = distance of fall in meters g = acceleration of gravity in meters / {sec}^{2} \\ t = time duration of fall in seconds v = terminal velocity in meters / sec \\ head = 1 / 2 \cdot 9.81 \cdot Δ g \cdot {t}^{2} [ for this hydro \text{-} electric case ] \\ t = {[ 2 / 9.81 \cdot Δ g \cdot head ]}^{1 / 2} \\ \begin{matrix}v = g \cdot Δ g \cdot t \\ = 9.81 \cdot 0.5 \cdot {[ 2 / 9.81 \cdot 0.5 \cdot head ]}^{1 / 2} \\ = 3.1 \times {head}^{1 / 2} meter \text{/} sec\end{matrix} \qquad ( DD \text{-} 2 )$$

Alternatively, the same result is obtained considering energy instead of distance and acceleration, as equation (DD-3).

$$Potential Energy converts to Kinetic Energy \\ head \cdot [ g \cdot m ] = 1 / 2 \cdot m \cdot {v}^{2} [ in general ] \\ \begin{matrix}v = {[ 2 \cdot head \cdot g \cdot Δ g ]}^{1 / 2} \\ = 3.1 \times {head}^{1 / 2} meter \text{/} sec\end{matrix} \qquad ( DD \text{-} 3 )$$

That acceleration applied repetitively to the water gives a final velocity dependent on the flow path structure and on the power delivered to the turbine. Typically, for a “very open” flow path structure, that final, steady state flow velocity could be on the order of two, five or more times the above calculated “terminal velocity”.

The length of the flow path is essentially twice the “head”, the water traveling the “head” once upward and once downward per cycle. The “very open” cross-section area of that flow path is one on the order of the square of half the head. The conservative flow calculation, using the equation (DD-3) velocity, is per equation (DD-4).

$$Flow path cross \text{-} section = {[ 1 / 2 \cdot head ]}^{2} \\ \begin{matrix}flow = velocity \times cross \text{-} section \\ = [ 3.1 \times {head}^{1 / 2} ] \cdot {[ 1 / 2 \cdot head ]}^{2} \\ = 0.78 \cdot {head}^{2.5} {meter}^{3} \text{/} sec\end{matrix} \qquad ( DD \text{-} 4 )$$

The resulting overall power output is per equation (DD-5).

$$\begin{matrix}P ≡ gravito \text{-} electric power output \\ = [ head \cdot Δ g ] \times flow \times efficiency \times factor \\ = [ head \cdot 0.5 ] \times [ 0.78 \cdot {head}^{2.5} ] \times efficiency \times factor \\ = 0.27 \cdot {head}^{3.0} \times efficiency \times 9.8 kilowatts\end{matrix} \qquad ( DD \text{-} 5 )$$

For a deflector that deflects only half the gravitation [Δg=0.5] as above and for a mechanical/electrical efficiency factor of 0.75, Table DD-1, on the following page, gives some sample values of gravito-electric outputs based on the above. As can be seen the output increases dramatically with physical size because of the exponents in equation (DD-5).

TABLE DD-1
Example Gravito-electric Power Outputs

| Head | Cross-section | Flow | Power | Power |
|---|---|---|---|---|
| meters | meters² | meters³/sec | kilowatts | horsepower |
| 1 | 0.25 | 0.78 | 2.0 | 2.7 |
| 2 | 1.0 | 4.4 | 16. | 21. |
| 5 | 6.3 | 44. | 250. | 330. |
| 10 | 25.0 | 250. | 2,000. | 2,700. |
| 20 | 100.0 | 1400. | 16,000. | 21,000. |

### [4] Design Considerations

[a] Configuration

Referring to Drawing 3, the effect of the gravitic deflector is not only to deflect gravitation away from the object above the deflector, but also to direct that deflected gravitation at an angle toward whatever surrounds the object above the deflector. In other words, the “direct effect” is that the object above the deflector is made to weigh less and the “indirect effect” is that its surroundings are made to weigh more.

The most efficient design for a gravito-electric generator is a circular arrangement as viewed from above as depicted in Drawing 6. The fluid above the gravitic deflector, which fluid is the upward path of the fluid circulation pattern, being surrounded by the downward return path of the fluid circulation is an arrangement that maximizes use of the above described “direct effect” and “indirect effect” of the gravitic deflector's action.

In addition, that arrangement is the most compact.

[b] The Working Fluid

The power output calculated per equation (DD-5) is based on the working fluid being fresh water, which has a density of 1,000 kg/meter³. Use of a more dense medium would directly proportionally increase the output power.

However, the vast majority of liquids have density near to that of water. In general the exceptions tend to have problems of potential corrosiveness or poisoning. The most dense liquids are:
Bromine @ 3.12 times the density of water,
Iodine @ 4.93 times the density of water, and
Mercury @ 13.5 times the density of water.

Another method to increase working fluid density would be to add granular high density particles to the fluid, the fluid being selected for the best viscosity compromise between the effect of the viscosity reducing flow velocity and sufficient viscosity to insure continuous sweeping of the added particles along with the fluid. In that regard water is a fairly viscous fluid and at reasonable velocity successfully sweeps particles along with its flow. The use of such particles might result in unacceptable levels of wear and damage to the turbine mechanisms.

It would appear that methods to increase output by increased working fluid density are not, for gravito-electric power stations, as economically viable as accomplishing equivalent output increase through larger sized gravito-electric units or a greater number of them in parallel and that water is the best working fluid.

[c] The Gravitic Deflector Design

Per the calculations of Section 4, a silicon monolithic cubic crystal slab 49 cm thick or more should result in 100% deflection.

Common commercially produced silicon cubic crystal wafers are on the order of 600 micro-meters [0.6 mm] thick and up to 30 cm in diameter. Using commercial wafers of that type with their very small thickness would be impractical.

Therefore a single thick slab is needed such as is commercially produced to form the ingot from which the commercial wafers are sliced.

With regard to the distance from the top of the cubic crystal deflector to the bottom of the object above it, the greater that distance is the more effectively reduced is the gravitational U-wave flux acting on the object because the scattered rays of gravitational U-wave can more effectively disperse as they have more distance to travel to the vicinity of the object.

The deflector consists of:
A support having a verified horizontal upper surface for the cubic crystal deflector;
A Silicon cubic crystal slab:
   30 cm in diameter,
   49 cm or more thick, and
   with the orientation of the cubic structure determined and noted so that the tilt-producing shims can be properly located at the mid-point of two adjacent sides of the horizontal plane of the cubic structure;
Precision shims 4.5 mm thick for producing the tilt of the cubic crystal slab: a tilt angle tangent of 0.015 producing a tilt angle of 0.86°. on the 30 cm diameter Silicon cubic crystal slab.

### [5] Gravitic Power Generation Compact Cases

On the other hand, for applications where minimizing the physical size of the gravito-electric generator relative to its output power is essential such as for land, sea, or air transportation vehicles an alternative arrangement would be appropriate. Such an alternative form is depicted in Drawing 6.

Here the generation of rotary motion to drive the electric generator is done by means of a flywheel. A massive wheel is schematically divided into two halves side by side horizontally. A gravitic deflector is placed into operation underneath one of the halves.

The result is that the part of the wheel above the deflector weighs less than that its other half. The lighter half rises while the heavier descends producing a continuous rotation. That rotation drives the turbine that drives the electric generator.

The output power calculations for this case are the same as for the case using water as the working fluid except that the flywheel's characteristics are substituted for those of water.
The density of the flywheel material would be on the order of ten times that of water. Therefore the “factor” of 9.8 for water becomes 98. for a typical flywheel.
The flow rate is the flywheel mass cross-sectional area times the tangential velocity of its center of mass.

The power equation then becomes as follows for the flywheel.

$$\begin{matrix}P = head \times flow \times efficiency \times factor \\ = head \cdot Δ g \times [ Cross \text{-} Section Area \times Rotation \\ Speed ] … … \times efficiency \times factor\end{matrix} \\ where \text{:} \\ \begin{matrix}head = height through which the flywheel mass \\ falls in meters \\ flow = flywheel mass cross \text{-} section times its \\ {centroid}^{′} s tangential velocity in {meter}^{3} \text{/} sec\end{matrix} \\ efficiency = fractional mechanical \text{/} electrical efficiency \\ \begin{matrix}factor = conversion factor \\ = 98. [ for typical flywheel material and natural \\ gravity of 9.81 meter \text{/} {sec}^{2} ]\end{matrix} \\ Δ g = factor for deflector effectiveness as before \qquad ( DD \text{-} 6 )$$

Assuming that the steady state velocity of the flywheel is ten times the “terminal velocity”, Table DD-3, below, gives some sample values of flywheel gravito-electric outputs for a deflector that deflects half the gravitation [Δg=0.5] as before above and for a mechanical/electrical efficiency factor of 0.75 as before above.

TABLE DD-3
Example Approximate Flywheel Gravito-electric Power Outputs

| | | Tangential | | |
|---|---|---|---|---|
| | Cross- | Rotation Speed | | |
| Head | section | 31 · head^{1/2} | Power | Power |
| meters | meters² | meters/sec | kilowatts | horsepower |
| 1 | 0.5 | 31 | 570 | 750 |
| 1 | 2. | 31 | 2,300 | 3,000 |
| 5 | 10. | 69 | 130,000 | 170,000 |

[5] http://en.wikipedia.org/wiki/Hydroelectricity

The claims are:

1. The use of arrangements of atoms, that is configurations of atoms in a piece of material and the orientation of the material relative to the gravitational field, such that for at and near one particular direction through that material the atoms are effectively so spaced, that is located, that all gravitational field acting through the material in that particular direction must pass so close to some atom in the material that the path of propagation of that gravitational field is deflected away from things on the side of the material opposite from that side at which the gravitational field first entered the material with the result that any object or objects on that far side of the material experience less gravitational action than they would otherwise have experienced; or

2. Such use of arrangements of atoms for gravito-electric power generation.

3. Such use of arrangements of atoms for reduced gravitation/reduced weight environments.
